(19) United States
(12) Patent Application Publication
(10) Pub. No.: US 2010/0073884 A1
(43) Pub. Date: Mar. 25, 2010

(54) LIGHT ENGINE, HEAT SINK AND ELECTRICAL PATH ASSEMBLY

(75) Inventor: Kirk B. Peloza, Naperville, IL (US)

Correspondence Address: MOLEX INCORPORATED, 2222 WELLINGTON COURT, LISLE, IL, 60532, US

(73) Assignee: MOLEX INCORPORATED, Lisle, IL (US)

(21) Appl. No.: 12/542,426

(22) Filed: Aug. 17, 2009

Related U.S. Application Data
(60) Provisional application No. 61/089,420, filed on Aug. 15, 2008.
(60) Provisional application No. 61/095,412, filed on Sep. 9, 2008.

(51) Int. Cl. H05K 7/20

(52) U.S. Cl. 361/710

(57) ABSTRACT

An assembly includes a conductive heat sink, a heat generating device, such as a light emitting diode, mounted on the heat sink, a pair of pins which extend through channels provided through the heat sink, and a pair of sleeves which at least partially surrounds the pins to electrically isolate the pins from the heat sink. The assembly can be used to form a lightbulb.

### RELATED APPLICATIONS

This application claims priority to U.S. provisional application Ser. No. 61/089,420, filed on Aug. 15, 2008, and to U.S. provisional application Ser. No. 61/095,412, filed Sep. 9, 2008, both of which are incorporated herein by reference in their entirety.

### FIELD OF THE INVENTION

The present invention relates to an assembly including a light engine, such as a solid state light engine, a heat sink and an electrical path assembly.

### BACKGROUND OF THE INVENTION

The use of solid state light (SSL) engines have become increasingly attractive as the need for energy efficient light sources has grown. SSLs have the potential to reduce energy used to produce a desired amount of light as well as last much longer then conventional lighting sources. For example, one type of SSL is a light omitting diode (LED). LEDs are now capable of producing light in the 150 lumens per watt (lm/w) and further improvements are expected. One issue that the use of SSL has raised, however, is the need to manage the heat generated by the SSL. LEDs, for example, can produce a significant amount of thermal energy in a relatively small area. To avoid damaging and reducing the efficiency of the SSL, it is beneficial to allow the generated heat a way to propagate away from the source. Therefore, improvements in how the module is configured would be appreciated by certain users.

### BRIEF SUMMARY OF THE INVENTION

An assembly includes a conductive heat sink, a solid state light engine, such as a light emitting diode, mounted on the heat sink, a pair of pins which extend through channels provided through the heat sink, and a pair of sleeves which at least partially surrounds the pins to electrically isolate the pins from the heat sink. The assembly can be used to form a lightbulb.

### BRIEF DESCRIPTION OF THE DRAWINGS

The organization and manner of the structure and operation of the invention, together with further objects and advantages thereof, may best be understood by reference to the following description, taken in connection with the accompanying drawings, in which:

FIG. 1 is a top perspective view of an assembly which incorporates the features of a first embodiment of the invention, the assembly including a heat generating source, a heat sink, an electrical path assembly, a top insulator and a bottom insulator;

FIG. 2 is a bottom perspective view of the assembly of FIG. 1;

FIG. 3 is a side elevational view of the assembly of FIG. 1;

FIG. 4 is a bottom plan view of the assembly of FIG. 1;

FIG. 5 is a cross-sectional view of the assembly along line 5-5 of FIG. 1;

FIG. 5A is an enlarged, partial top plan view of a portion of the heat sink of FIG. 1;

FIG. 5B is an enlarged, partial top plan view of another portion of the heat sink of FIG. 1;

FIG. 6 is a perspective view of a portion of the electrical path assembly and the heat generating source of FIG. 1;

FIG. 7 is a perspective view of a portion of a pin used in the electrical path assembly of FIG. 1;

FIG. 8 is a perspective view of a sleeve and a pin used in the electrical path assembly of FIG. 1;

FIG. 9 is a bottom plan view of the sleeve of FIG. 8;

FIG. 10 is a perspective view of the electrical path assembly of FIG. 1, disassembled from the heat sink;

FIG. 11 is a cross-sectional view along line 11-11 of FIG. 1, with a portion of the electrical path assembly removed;

FIG. 12 is a bottom perspective view of the heat generating device of FIG. 1;

FIG. 13 is a perspective view of some of the components of the assembly of FIG. 1 showing the assembly process;

FIG. 14 is an enlarged perspective view of a portion of the electrical path assembly of FIG. 1 shown pulled apart for illustrating features of the invention;

FIG. 15 is an enlarged perspective view of a portion of the electrical path assembly of FIG. 1;

FIG. 16 is a perspective view of the components of the assembly of FIG. 1 showing the final assembly process;

FIG. 17 is an enlarged perspective view of a portion of the electrical path assembly shown assembled with the heat sink of FIG. 1;

FIGS. 18A-18D show alternate tips for the pins used in the electrical path assembly of the present invention;

FIG. 19 is a top perspective view of an assembly which incorporates the features of a second embodiment of the invention, the assembly including a heat generating source, a heat sink and an electrical path assembly;

FIG. 20 is a bottom perspective view of the assembly of FIG. 19;

FIG. 21 is a perspective view of a portion of the electrical path assembly and the heat generating source of FIG. 1;

FIG. 22 is a top perspective view of the heat sink of FIG. 19 having one of the pins of the electrical path assembly mounted therein;

FIG. 23 is a perspective view of some of the components of the first embodiment and some of the components of the second embodiment showing the assembly process;

FIG. 24 is a top perspective view of an assembly having the components shown in FIG. 23;

FIG. 25 is a bottom perspective view of the assembly of FIG. 24;

FIG. 26 is a top perspective view of an assembly which incorporates the features of a third embodiment of the invention, the assembly including a heat generating source, a heat sink and an electrical path assembly;

FIG. 27 is a bottom perspective view of the assembly of FIG. 26;

FIG. 28 is a top perspective view of the assembly of FIG. 26 with the heat generating source removed;

FIG. 29 is a top perspective view of the heat sink of FIG. 26;

FIG. 30 is a perspective view of a housing which is a component of the electrical path assembly of FIG. 26;

FIG. 31 is a perspective view of a pin and resistor which are components of the assembly of FIG. 26;

FIG. 32 is a perspective view of the pin and resistor of FIG. 31 mounted on the housing of FIG. 30;

FIG. 33 is a perspective view some of the components of the electrical path assembly of FIG. 26 in an exploded condition and separated from heat sink of FIG. 26;

FIG. 34 is a cross-sectional view some of the components of FIG. 32 and separated from heat sink of FIG. 26;

FIG. 35 is a perspective view of the components of the assembly of FIG. 26 showing the assembly process;

FIG. 36 is an enlarged perspective view of a portion of assembly of FIG. 26;

FIG. 37 is a top perspective view of the assembly of FIG. 26, including a top insulator;

FIG. 38 is a modified sleeve with a pin attached thereto for use with the assembly of FIG. 26;

FIG. 39 is a cross-sectional view along line 39-39 of FIG. 38;

FIG. 40 is a top perspective view of an assembly which incorporates the features of a fourth embodiment of the invention, the assembly including a heat generating source, a heat sink and an electrical path assembly;

FIG. 41 is a top plan view of the heat sink of FIG. 40;

FIG. 42 is a top perspective view of the assembly of FIG. 40 with the heat sink removed;

FIG. 43 is a side elevational view of a portion of the electrical path assembly of FIG. 40;

FIG. 44 is a perspective view of a lightbulb assembly incorporating the assembly of FIG. 40;

FIG. 45 is a side elevational view of a portion of a component of the lightbulb assembly of FIG. 44;

FIG. 46 is a side elevational view of another portion of a component of the lightbulb assembly of FIG. 44;

FIG. 47 is a top perspective view of a component of the lightbulb assembly being assembled with the assembly of FIG. 40;

FIG. 48 is a cross-section view of the components shown in FIG. 48 after assembly;

FIG. 49 is a top perspective view assembled components shown in FIG. 48 being assembled with a further component of the lightbulb assembly;

FIG. 50 is a cross-section view of the lightbulb assembly of FIG. 44;

FIG. 51 is a perspective view of a modified housing;

FIG. 52 is a bottom perspective view of a lightbulb assembly using the modified housing of FIG. 51;

FIG. 53 is a top perspective view of a lightbulb assembly using the modified housing of FIG. 51;

FIG. 54 is a top perspective view of an assembly which incorporates the features of a fifth embodiment of the invention, the assembly including a heat generating source, a heat sink and an electrical path assembly;

FIG. 55 is a perspective view of the assembly of FIG. 54;

FIG. 56 is a perspective view of the electrical path assembly of FIG. 54;

FIG. 57 is an alternate perspective view of the electrical path assembly of FIG. 54;

FIG. 58 is a perspective view of the pins used in the electrical path assembly of FIG. 54;

FIG. 59 is a top perspective view of the assembly of FIG. 54 with the heat generating device removed; and

FIG. 60 is a perspective view of the components of the assembly of FIG. 54 showing the assembly process.

### DETAILED DESCRIPTION OF THE ILLUSTRATED EMBODIMENTS

While the invention may be susceptible to embodiment in different forms, there is shown in the drawings, and herein will be described in detail, specific embodiments with the understanding that the present disclosure is to be considered an exemplification of the principles of the invention, and is not intended to limit the invention to that as illustrated and described herein. While directional terms, such as upper, lower, top, bottom and the like are used herein, these do not denote a specific desired orientation and instead are used for ease in describing the present invention.

The depicted embodiments are illustrated as being used with a light emitting diode (LED) device 20, however, the design is not so limited. Therefore, the depicted configurations may also be used with other types of solid state lighting (SSL) engines. Therefore, the discussion below with respect to LED devices may also be applied to other SSLs. However, for ease of discussion only an LED device will be expressly mentioned.

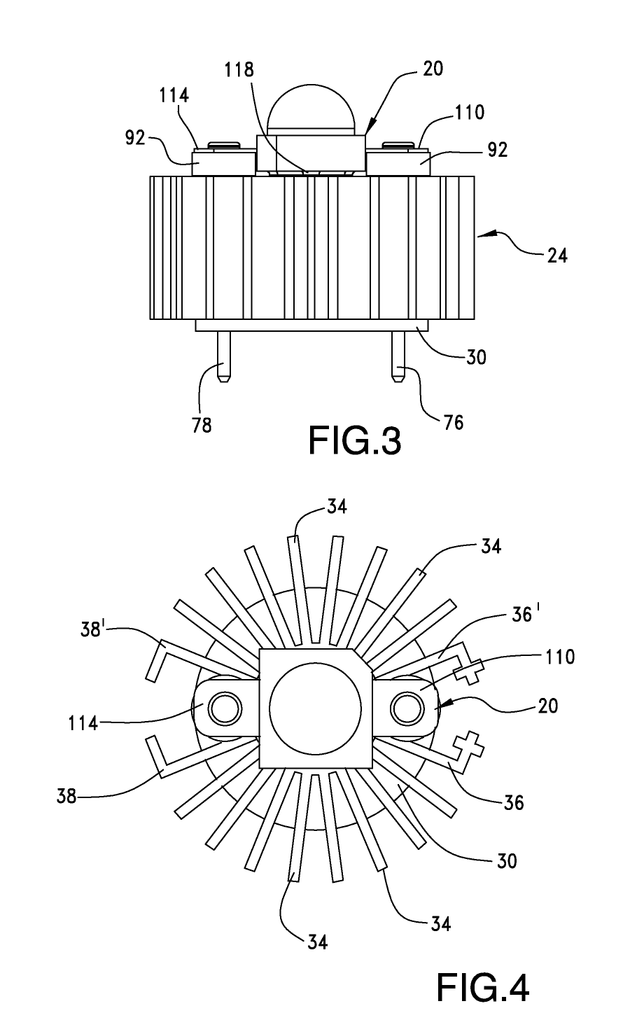

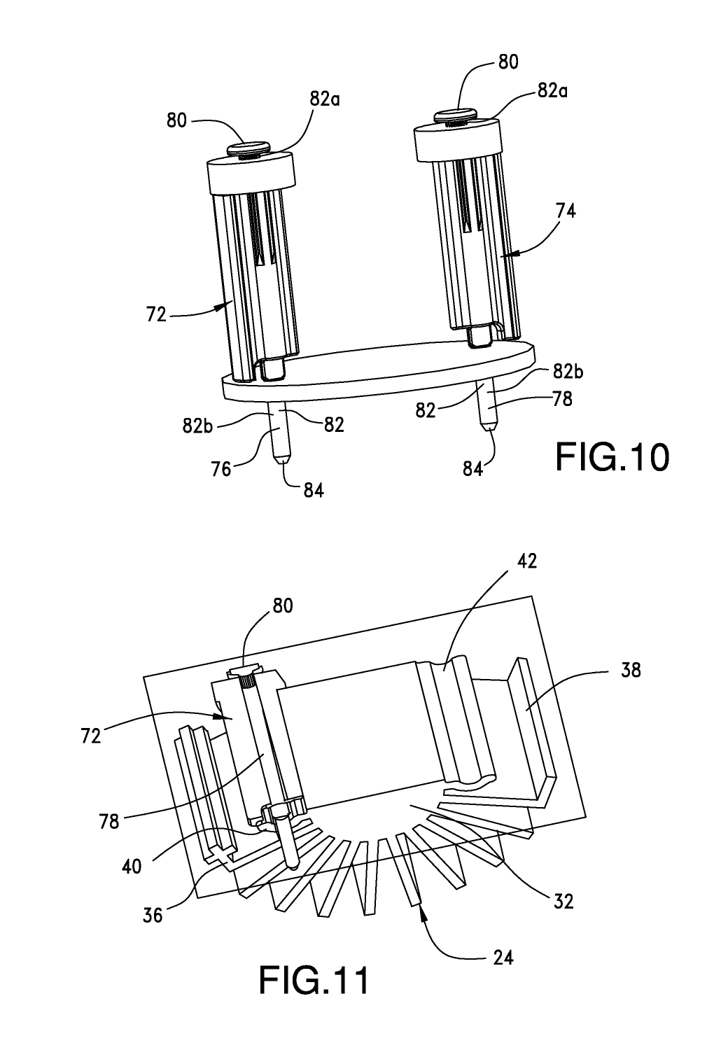

Attention is invited to the first embodiment of an assembly 22 shown in FIGS. 1-17. The assembly includes the LED device 20, a heat sink 24, an electrical path assembly 26, a top insulator 28 and a bottom insulator 30. While top and bottom insulators 28, 30 are shown and described, it is to be understood that the necessity of these components is dependent upon the type of LED device 20 used.

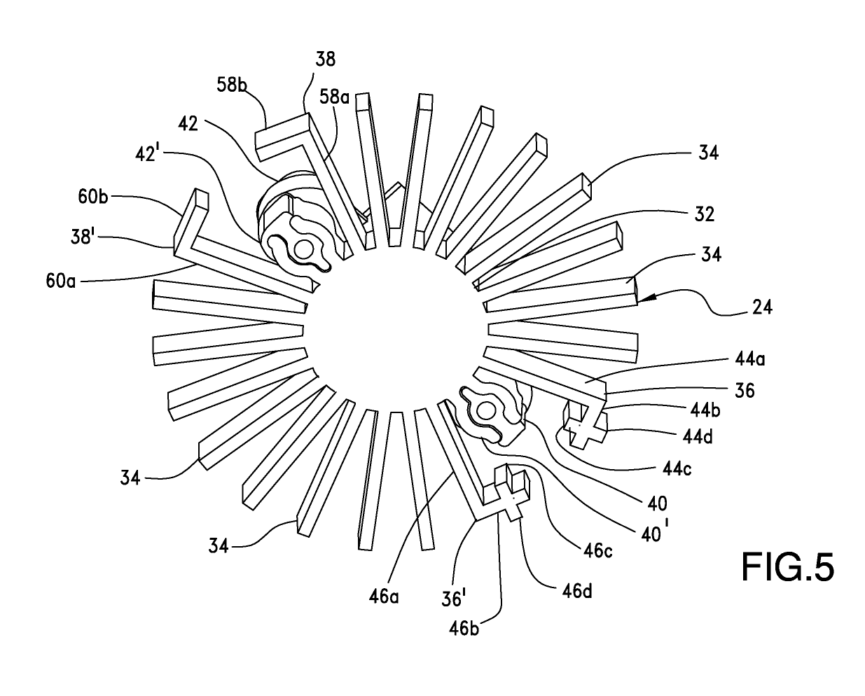

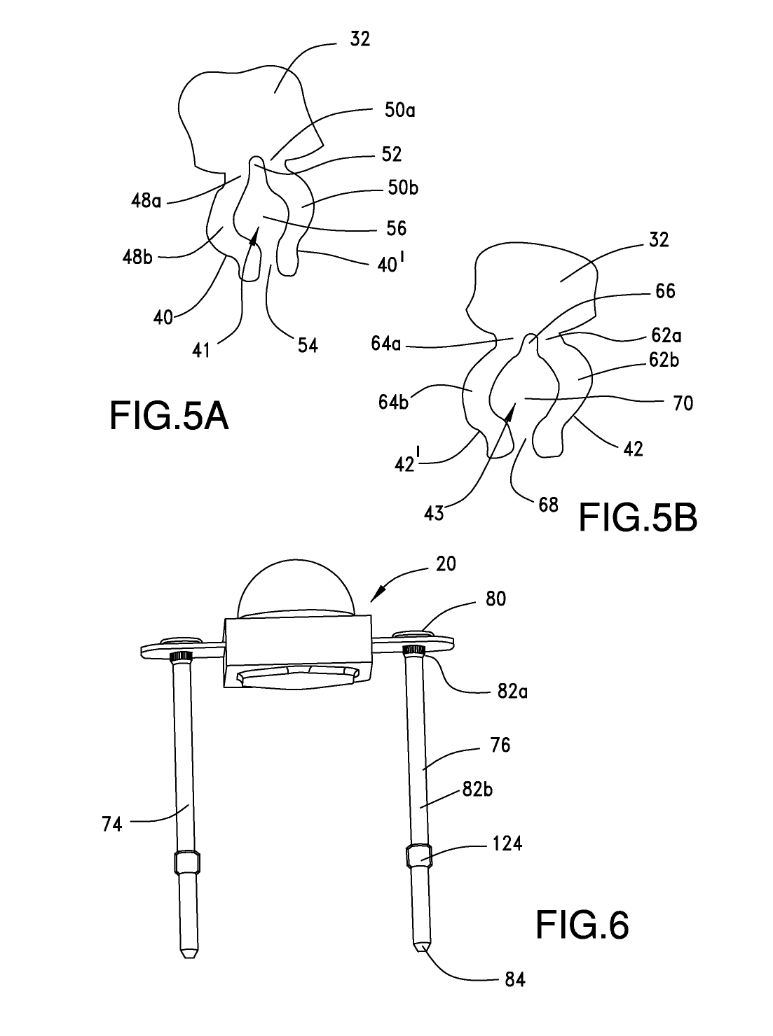

As best shown in FIG. 5, the heat sink 24 includes a base 32 having a plurality of spaced apart fins 34 extending from the exterior of the base 32, a first pair of locating fins 36, 36′ extending from the exterior of the base 32, a second pair of locating fins 38, 38′ extending from the exterior of the base 32, a first pair of electrical path retaining fins 40, 40′ extending from the exterior of the base 32, and a second pair of electrical path retaining fins 42, 42′ extending from the exterior of the base 32. The heat sink 24 is conventionally made of extruded aluminum and provides surface area for heat dissipation from the LED device 20.

The exterior of the base 32 is generally cylindrical. The top surface and the bottom surface of the base 32 are generally planar.

The first pair of locating fins 36, 36′ extend from one side of the base 32, and the second pair of locating fins 38, 38′ extend from the diametrically-opposed side of the base 32. The first pair of electrical path retaining fins 40, 40′ are positioned between the first pair of locating fins 36, 36′. The second pair of electrical path retaining fins 42, 42′ are positioned between the second pair of locating fins 38, 38′.

The first pair of locating fins 36, 36′ includes a first fin 36 and a second fin 36′. The first fin 36 is formed of a first leg 44a which extends generally radially outwardly from the base 32 at a first end thereof, a second leg 44b at the second end of the first leg 44a which extends generally perpendicular to the first leg 44a, a third leg 44c which extends perpendicularly from the second leg 44b toward the base 32, and a fourth leg 44d which extends perpendicularly from the second leg 44b away from the base 32. The third and fourth legs 44c, 44d are in the same plane. The second fin 36′ has a first leg 46a which extend radially outwardly from the base 32 at a first end thereof, a second leg 46b at the second end of the first leg 46a which extends generally perpendicular to the first leg 46a, a third leg 46c which extends perpendicularly from the second leg 46b toward the base 32, and a fourth leg 46d which extends perpendicularly from the second leg 46b away from the base 32. The third and fourth legs 46c, 46d are in the same plane. The second legs 44b, 46b extend toward each other, but are separated from each other such that a gap is provided between the ends of the second legs 44b, 46b. Each fin 36, 36′ extends from the top end to the bottom end of the base 32.

The first pair of electrical path retaining fins 40, 40′ are best shown in FIG. 5A, and include a first fin 40 and a second fin 40′. The first fin 40 is spaced from the first fin 36. The second fin 40′ is spaced from the second fin 36′ and from the first fin 40. A channel 41 is provided between the first fin 40 and the second fin 40′. The first fin 40 has first section 48a which extends generally radially outwardly from the base 32, and a second section 48b which is arcuate. The second fin 40′ has first section 50a which extends generally radially outwardly from the base 32, and a second section 50b which is arcuate. The first sections 48a, 50a are spaced apart from each other to form a pocket 52 of the channel 41. The ends of the second sections 48b, 50b are spaced apart from each other to form a slot 54 of the channel 41. The area between the arcuate second sections 48b, 50b form a gap 56 of the channel 41. Each fin 40, 40′ extends from the top end to the bottom end of the base 32.

The second pair of locating fins 38, 38′ includes a first fin 38 and a second fin 38′. The first fin 38 is formed of a first leg 58a which extends generally radially outwardly from the base 32 and a second leg 58b at the opposite end of the first leg 58a which extends generally perpendicular to the first leg 58a. The second fin 38′ has a first leg 60a which extends generally radially outwardly from the base 32 and a second leg 60b at the opposite end of the first leg 60a which extends generally perpendicular to the first leg 60a. The second legs 58b, 60b extend toward each other, but are separated from each other such that a gap is provided between the ends of the second legs 58b, 60b. Each fin 38, 38′ extends from the top end to the bottom end of the base 32.

The second pair of electrical path retaining fins 42, 42′ are best shown in FIG. 5B, and include a first fin 42 and a second fin 42′. The first fin 42 is spaced from the first fin 38. The second fin 42′ is spaced from the second fin 38′ and from the first fin 42. A channel 43 is provided between the first fin 42 and the second fin 42′. The first fin 42 has first section 62a which extends generally radially outwardly from the base 32, and a second section 62b which is arcuate. The second fin 42′ has first section 64a which extends generally radially outwardly from the base 32, and a second section 64b which is arcuate. The first sections 62a, 64a are spaced apart from each other to form a pocket 66 of the channel 43. The ends of the second sections 62b, 64b are spaced apart from each other to form a slot 68 of the channel 43. The area between the arcuate second sections 62b, 64b form a gap 70 of the channel 43. Each fin 42, 42′ extends from the top end to the bottom end of the base 32.

A plurality of the fins 34 are provided at spaced apart locations along the exterior of the base 32 between the first and second pairs of locating fins 36, 36′; 38, 38′. Each fin 34 extends radially outwardly from the base 32 and extends from the top end to the bottom end of the base 32.

The electrical path assembly 26 is used to connect the LED device 20 to the power source or circuit member (not shown) and is best shown in FIGS. 6-11. The electrical path assembly 26 includes first and second sleeves 72, 74 and first and second pins 76, 78. The sleeves 72, 74 are mounted within the channels 41, 43 as described herein.

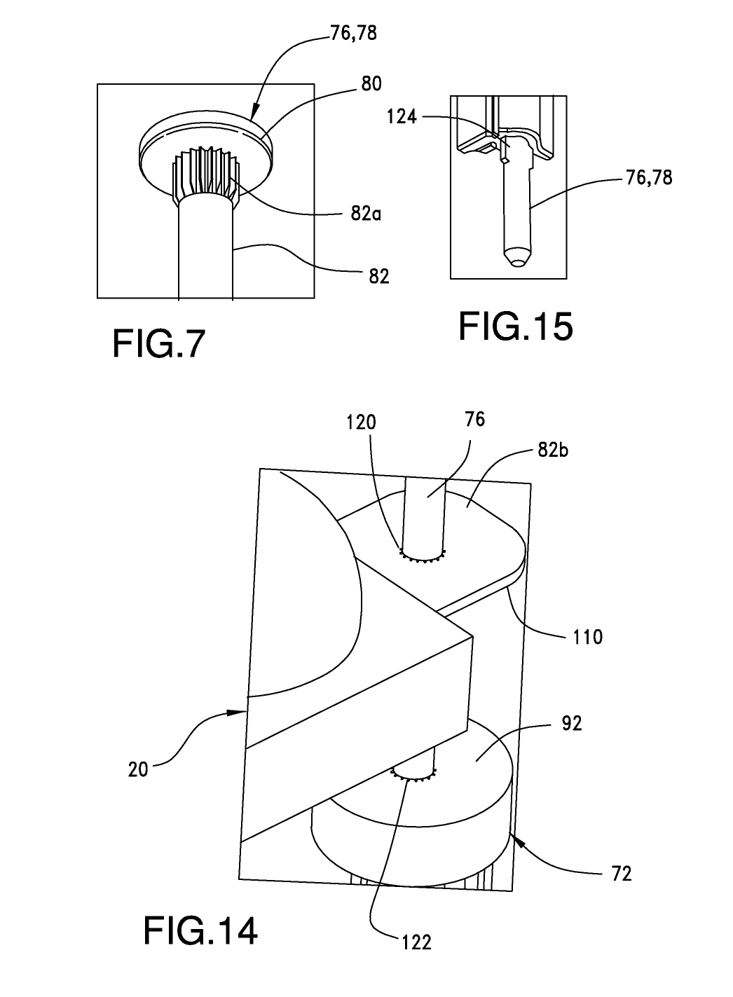

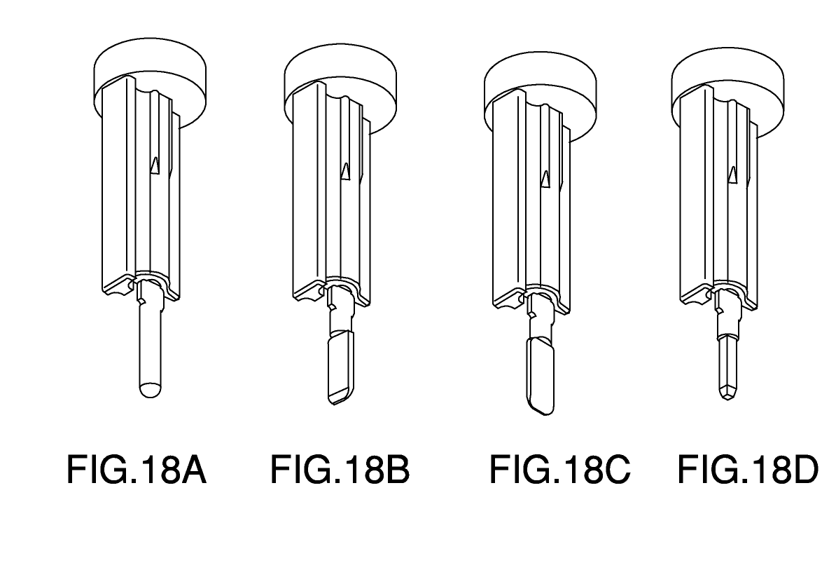

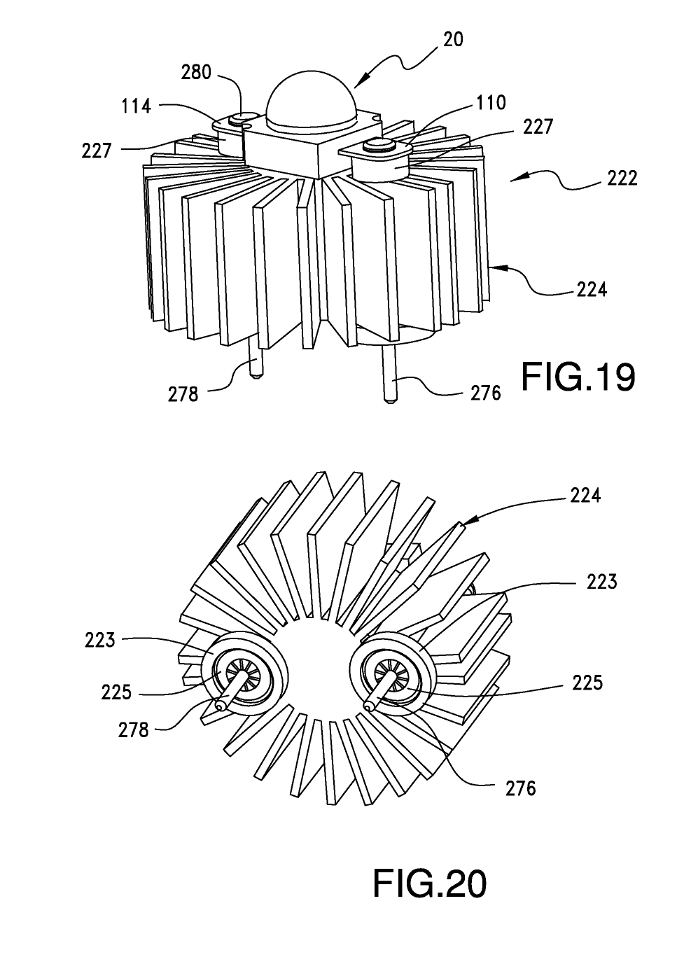

Each pin 76, 78 is electrically conductive and includes a head 80 and an elongated cylindrical shank 82 extending therefrom to a tip 84. As shown in FIGS. 6, 8 and 10, a solder tip 84 is provided, but the tip 84 may take other forms as shown in FIGS. 18A-18D (FIG. 18A shows a pin terminal tip; FIG. 18B shows a male tab terminal or weld surface; FIG. 18C shows a an alternate male tab terminal or weld surface; and FIG. 18D shows a rectangular pin). Each shank 82 includes a first section 82a which extends from the head 80 and a second section 82b which extends from the first section 82a to the tip 84. Each first section 82a is knurled as best shown in FIG. 7.

The first and second sleeves 72, 74 are dielectric. Sleeve 72 is described with the understanding that sleeve 74 is identically formed.

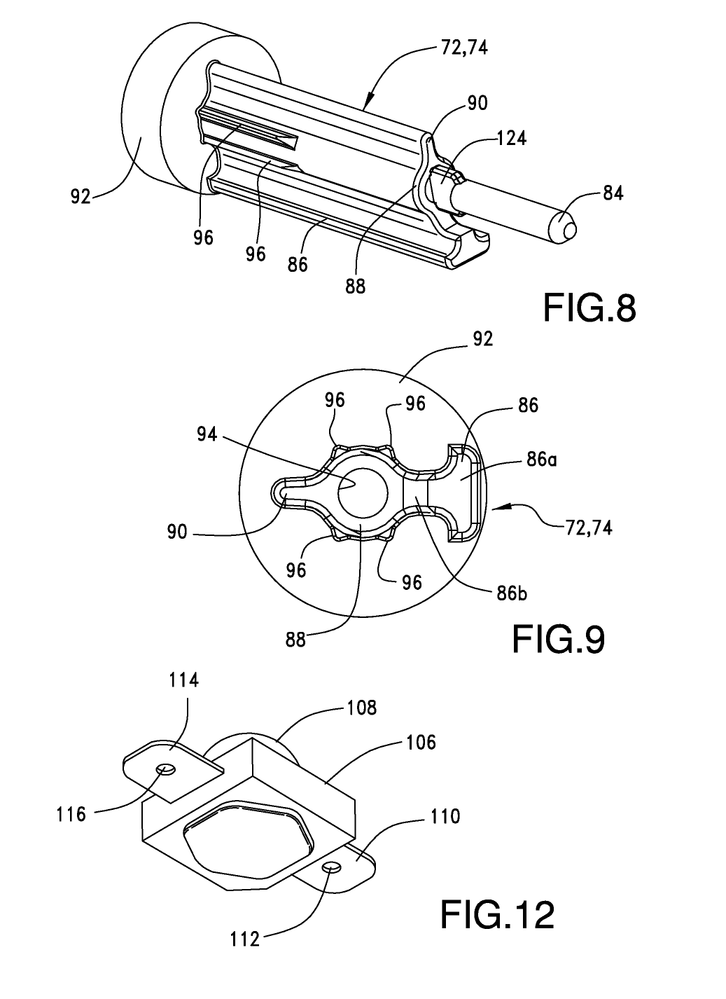

As best shown in FIGS. 8 and 9, the sleeve 72 has an elongated base wall 86, an elongated tubular wall 88 extending from the base wall 86, an elongated finger wall 90 extending outwardly from the tubular wall 88, and a cap 92 provided at a top end of the walls 86, 88, 90. The components of the sleeve 72 are integrally formed and may be molded.

The base wall 86 has a first enlarged section 86a and a second reduced section 86b. The tubular wall 88 extends from the second reduced section 86b. The width of the enlarged section 86a is greater than the width of the reduced section 86b. The reduced section 86b has a dimension which is slightly less than the width of the slot 54, 68 between the ends of the electrical path retaining fins 40, 40′; 42, 42′.

The tubular wall 88 has a central passageway 94 therethrough. Elongated ribs 96 are provided at spaced apart locations on the exterior of the tubular wall 88. The lower end of the ribs 96 may be beveled. Preferably, the tubular wall 88 is cylindrical, but it is not limited to this shape, provided the gaps 56, 70 mirror the shape of the wall 88. The tubular wall 88 extends from the top end of the base wall 86 to a point which is spaced from the lower end of the base wall 86.

The cap 92 is generally cylindrical and has an aperture 98 provided therethrough. The aperture 98 is preferably the same diameter as the central passageway 94 and has substantially the same diameter as the second sections 82b of the pins 76, 78. The cap 92 has a diameter which is larger than the diameter of the tubular wall 88, and is preferably cylindrical. Like the tubular wall 88, the cap 92 is not limited to a cylindrical shape.

The finger wall 90 extends from the diametrically opposed side of the tubular wall 88 to that from which the base wall 86 extends. The finger wall 90 has a width which is substantially less than the width of the tubular wall 88.

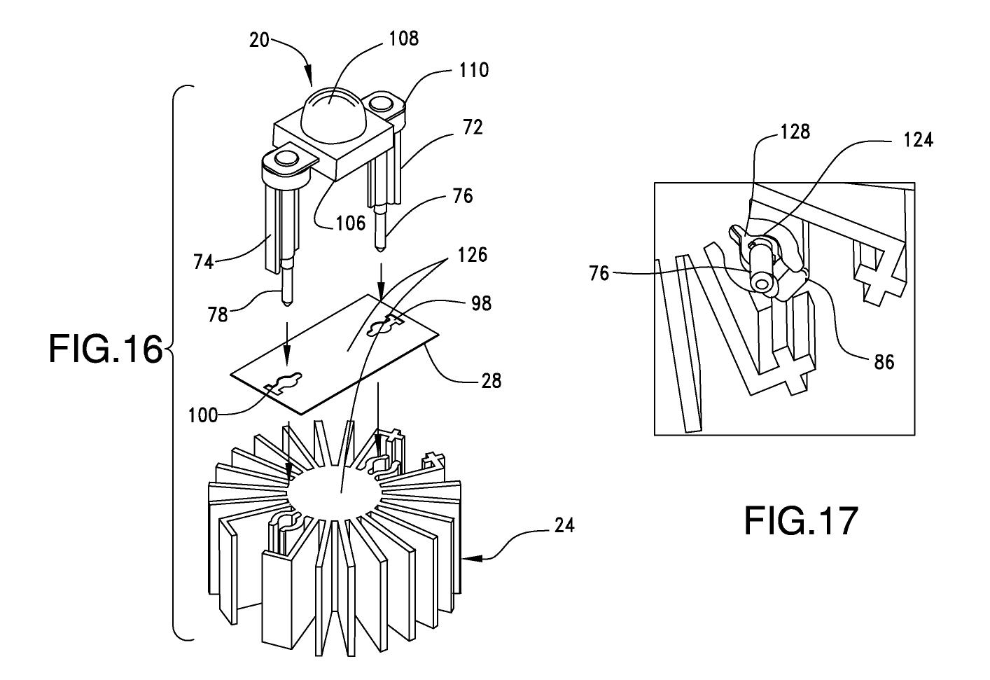

As best shown in FIG. 16, the top insulator 28 is a thin sheet of solid material and is dielectric. The top insulator 28 is mounted between the heat sink 24 and LED device 20. The top insulator 28 is preferably rectangular and has a pair of spaced apart apertures 98, 100 provided therethrough through which the base wall 86, the tubular wall 88 and the elongated finger wall 90 extend. Preferably and as shown in FIG. 16, the apertures 98, 100 in the top insulator 28 mirror the shape of the walls 86, 88, 90. It is to be understood that the top insulator 28 may take other shapes provided the top insulator 28 electrically isolates the LED device 20 from the heat sink 24.

The bottom insulator 30 is dielectric and is mounted between the heat sink 24 and the power source or circuit member. The bottom insulator 30 is preferably circular and has a pair of spaced apart apertures 102, 104 provided therethrough through which the second section 82b of the pins 76, 78 extend. It is to be understood that the bottom insulator 30 may take other shapes provided the bottom insulator 30 electrically isolates the power source or circuit member from the heat sink 24.

As shown in FIG. 12, the LED device 20 is formed from a substrate 106 on which at least one LED is provided. A lens cover 108 is provided over the at least one LED. A first lead 110 has an end electrically connected, for example by wire bonding, to the silicant in the substrate 106, and the other end of the first lead 110 has an aperture 112 through which the first pin 76 passes to electrically connected the first lead 110 to the first pin 76 as described herein. A second lead 114, which is electrically isolated from the first lead 110, has an end electrically connected, for example by wire bonding, to the silicant in the substrate 106, and the other end of the second lead 114 has an aperture 116 through which the second pin 78 passes to electrically connected the second lead 114 to the second pin 78 as described herein. The pins 76, 78 form an anode and a cathode for the LED device 20. A slug 118, which is formed of a solid piece of metal, is attached to the bottom surface of the substrate 106. The slug 118 provides the interface that transfers heat to the atmosphere.

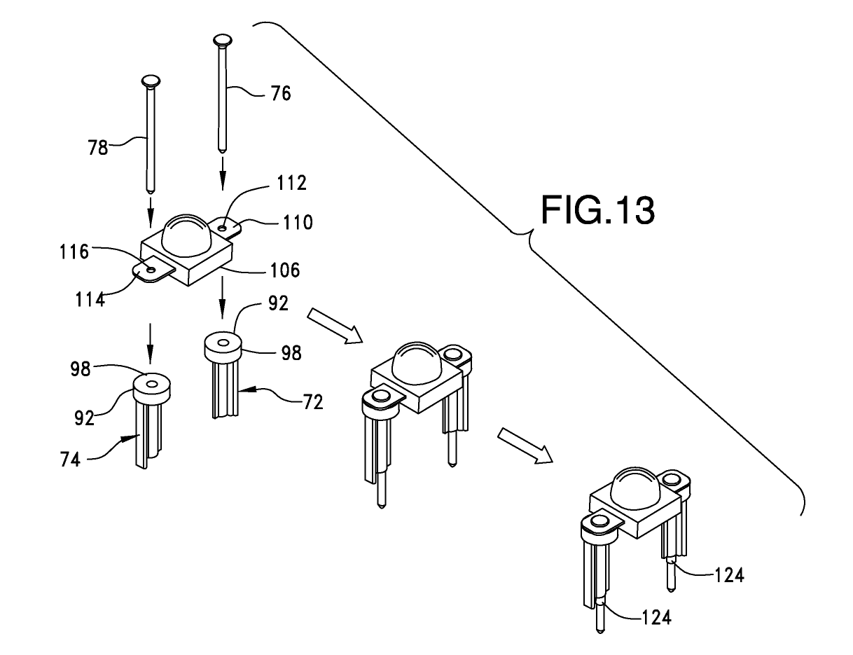

The assembly of the electrical path assembly 26 with the LED device 20 is shown in FIG. 13. To assemble these components, the first and second leads 110, 114 of the LED device 20 are seated on top of the caps 92 such that the substrate 106 of the LED device 20 is between the caps 92. The finger walls 90 of the sleeves 72, 74 face each other. The apertures 112, 114 through the first and second leads 110, 114 are aligned with the apertures 98 through the caps 92.

Next, the pins 76, 78 are inserted through the apertures 112, 116 in the first and second leads 110, 114, through the apertures 98 in the caps 92, and through the central passageways 94 of the sleeves 72, 74. The heads 80 of the pins 76, 78 bear against the top surfaces of the first and second leads 110, 114, but because the apertures 112, 116 through the first and second leads 110, 114 are smaller than the heads 80, the heads 80 do not pass through the first and second leads 110, 114. The knurled first section 82a of each pin 76, 78 engages with the first and second leads 110, 114 and the caps 92. The knurled first section 82a cuts a serrated pattern 122 into the first and second leads 110, 114 which prevent the pins 76, 78 from rotating relative to the first and second leads 110, 114. In addition, the knurled first section 82a causes a hoop stress which results in an inwardly radial force to secure and stabilize the electrical connection between the pins 76, 78 and the first and second leads 110, 114. The knurled first section 82a also cuts a serrated pattern 124 into each cap 92 which prevents the pins 76, 78 from rotating relative to the sleeves 72, 74, and secures the sleeves 72, 74 to the first and second leads 110, 114. FIG. 14 shows the LED device 20, pin 76 and sleeve 72 pulled apart after assembly to illustrate the serrated patterns 120, 122 formed in the leads 110, 114 and the caps 92. If desired, the heads 80 of the pins 76, 78 and the leads 110, 114 can be soldered together to further secure the connection.

After assembly, the second section 82b of each pin 76, 78 is seated within the cap 92 and the tubular wall 88, and a lower portion of the second section 82b extends outwardly from the bottom of the tubular wall 88. Thereafter, a section of this lower portion of the second section 82b of each pin is swaged by known means to form a flat 124, see FIG. 15, just below the lower end of the respective sleeve 72, 76. As a result, the LED device 20, sleeves 72, 76 and pins 76, 78 are securely fastened to each other.

Next, a thermally conductive grease or adhesive 126 is applied to the upper surface of the top insulator 28 and to the upper surface of the base 32 of the heat sink 24. The top insulator 28 is attached to the sleeves 72, 74 by passing the respective walls 86, 88, 90 through the apertures 98, 100 in the top insulator 28. When the apertures 98, 100 in the top insulator 28 mirror the shape of the walls 86, 88, 90, this prevents the top insulator 28 from moving relative to the sleeves 72, 74. As a result, the caps 92 abut the top surface of the top insulator 28. The top insulator 28 abuts against the slug 118 on the LED device 20. The thermally conductive grease or adhesive fills in surface irregularities to facilitate heat transfer between the heat sink 24 and the LED device 20 when they are assembled together.

The sleeves 72, 74 are then inserted between the respective electrical path retaining fins 40, 40′; 42, 42′. For sleeve 72, the finger wall 90 is inserted into the pocket 52, the tubular wall 88 is inserted into the gap 56 and the reduced section 86b of the base wall 86 is inserted into the slot 54; the enlarged section 86a of the base wall 86 is outside of the ends of the fins 40, 40′. For sleeve 74, the finger wall 90 is inserted into the pocket 66, the tubular wall 88 is inserted into the channel 70 and the reduced section 86b of the base wall 86 is inserted into the slot 68; the enlarged section 86a of the base wall 86 is outside of the ends of the fins 42, 42′. During assembly, the ribs 96 on the sleeves 72, 74 are crushed against the interior surfaces of the arcuate second sections 48b, 50b; 62b, 64b to form a friction fit between the sleeves 72, 74 and the fins 40, 40′; 42, 42′. The crushed ribs 96 also provide mechanical stability between the LED device 20, the sleeves 72, 74 and the heat sink 24 which protects the electrical connection and the thermal connection. The attachment formed between the sleeves 72, 74 and the electrical path retaining fins 40, 40′; 42, 42′ by the friction fit may be augmented by thermally conductive adhesive provided between the sleeves 72, 74 and the electrical path retaining fins 40, 40′; 42, 42′. The bottom end of each base wall 86 aligns with the respective bottom end of the electrical path retaining fins 40, 40′; 42, 42′. Since the tubular wall 88 and finger wall 90 do not extend the full length of the base wall 86, a pocket 128 is formed around the swaged flat 124 on each pin 76, 78 by the base wall 86, the bottom ends of the tubular wall 88 and finger wall 90 and the electrical path retaining fins 40, 40′; 42, 42′. If desired, this pocket 128 can be filled with non-electrically conductive adhesive or potting resin to improve the retention of the sleeves 72, 74 with the heat sink 24, or to improve the electrical insulation between the pins 76, 78 and the heat sink 24. Alternatively, this pocket 128 can remain unfilled with the air gap providing the electrical insulation.

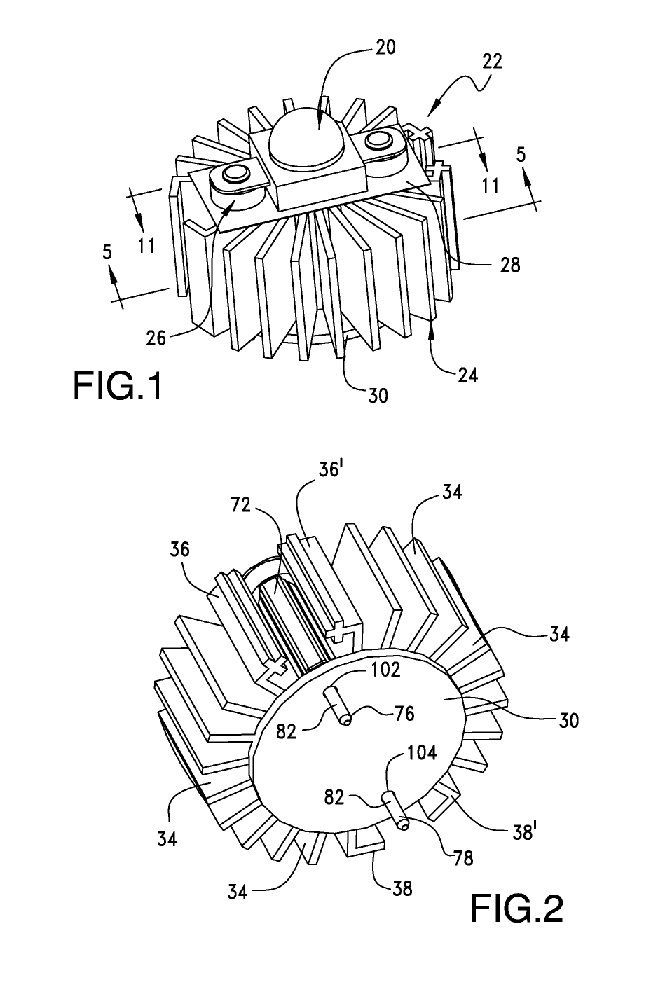

When the sleeves 72, 74 are fully inserted, a portion of each second section 82b of the pins 76, 78 extends downwardly from the heat sink 24. The second section 82b of each pin 76, 78 is passed through and extends from the respective aperture 102, 104 in the bottom insulator 30, see FIG. 2. The bottom insulator 30 abuts the lower end of the heat sink 24. The ends of the pins 76, 78 can be friction fit, or otherwise secured, to the power source or circuit member.

Therefore, an anode of the LED device 20 is formed by the first lead 110 and the first pin 76, and a cathode of the LED device 20 is formed by the second lead 114 and the second pin 78. The second, third and fourth legs 44b, 44c, 44d; 46b, 46c, 46d of the locating fins 36, 36′ form a “plus” sign to denote that this is the anode of the LED device 20. The second legs 58b, 60b of the locating fins 38, 38′ form a “minus” to denote that this is the cathode of the LED device 20. The anode and the cathode are electrically isolated from each other by the top insulator 28 (if provided), the sleeves 72, 74 and the bottom insulator 30 (if provided). This provides for an electrical path between the power source or circuit member and the LED device 20. As a result, a heat sink function and an electrical path retaining function are provided. During operation of the LED device 20, the LED device 20 generates heat which is transferred to the base 32 and to the fins 34, 36, 36′, 38, 38′, 40, 40′, 42, 42′, and this heat must be removed. As air is circulated around the base 32 by known means, the heat is removed.

Attention is invited to the second embodiment of an assembly 222 shown in FIGS. 19-22. The assembly includes the LED device 20, a heat sink 224 and an electrical path assembly 226. Although a top insulator 28 and a bottom insulator 30 are not shown, they may be used in this second embodiment in the same manner as that provided in the first embodiment. The LED device 20 as shown is identical to that shown in the first embodiment. Therefore, the specifics of the LED device 20 are not repeated.

As best shown in FIG. 22, the heat sink 224 includes a base 232 having a plurality of spaced apart fins 234 extending from the exterior of the base 232, a first pair of electrical path retaining fins 240, 240′ extending from the exterior of the base 232, and a second pair of electrical path retaining fins 242, 242′ extending from the exterior of the base 232. The heat sink 224 is conventionally made of extruded aluminum and provides surface area for heat dissipation from the LED device 20.

The exterior of the base 232 is generally cylindrical. The top surface and the bottom surface of the base 232 are generally planar

The first pair of electrical path retaining fins 240, 240′ include a first fin 240 and a second fin 240′ which are spaced apart from each other. The first fin 240 has first section 248a which extends generally radially outwardly from the base 232, a second section 248b which is arcuate, and a third section 248c which extends generally radially outwardly relative to the base 232. The second fin 240′ has first section 250a which extends generally radially outwardly from the base 232, a second section 250b which is arcuate, and a third section 250c which extends generally radially outwardly relative to the base 232. The first sections 248a, 250a are spaced apart from each other to form a pocket. The third sections 248c, 250c are spaced apart from each other to form a slot. The area between the arcuate second sections 248b, 250b form a gap or channel 256. Each fin 240, 240′ extends from the top end to the bottom end of the base 232.

The second pair of electrical path retaining fins 242, 242′ include a first fin 242 and a second fin 242′ which are spaced apart from each other. The first fin 242 has first section 262a which extends generally radially outwardly from the base 232, a second section 262b which is arcuate, and a third section 262c which extends generally radially outwardly relative to the base 232. The second fin 242′ has first section 264a which extends generally radially outwardly from the base 232, a second section 264b which is arcuate, and a third section 264c which extends generally radially outwardly relative to the base 232. The first sections 262a, 264a are spaced apart from each other to form a pocket. The third sections 262c, 264c are spaced apart from each other to form a slot. The area between the arcuate second sections 262b, 264b form a gap or channel 270. Each fin 242, 242′ extends from the top end to the bottom end of the base 232.

A plurality of the fins 234 are provided at spaced apart locations along the exterior of the base 232 between the first and second pairs of electrical path retaining fins 240, 240′; 242, 242′. Each fin 234 extends radially outwardly from the base 232 and extends from the top end to the bottom end of the base 232.

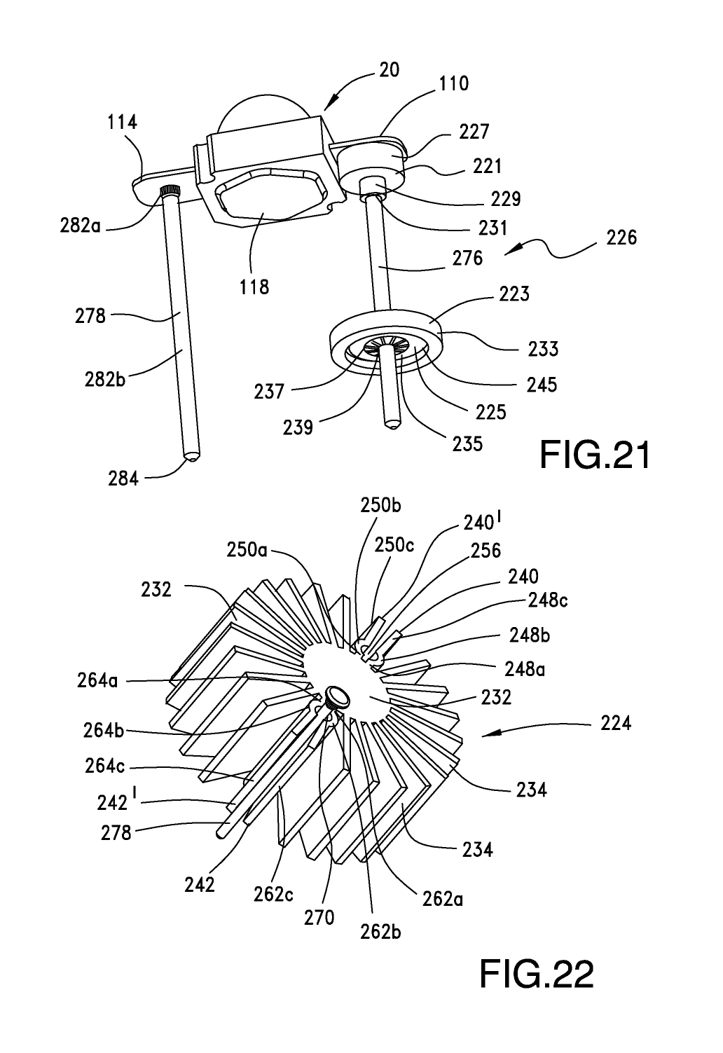

The electrical path assembly 226 is used to connect the LED device 20 to the power source or circuit member (not shown) and is best shown in FIG. 21. The electrical path assembly 226 includes first and second sleeves 272, 274 and first and second pins 276, 278. The sleeves 272, 274 are mounted within the gaps or channels 256, 270 as described herein.

Each pin 276, 278 is electrically conductive and includes a head 280 and an elongated cylindrical shank 282 extending therefrom to a tip 284. As shown in this embodiment, a solder tip 284 is provided, but the tip 284 may take other forms as shown in FIGS. 18A-18D. Each shank 282 includes a first section 282a which extends from the head 280 and a second section 282b which extends from the first section 282a to the tip 284. Each first section 282a is knurled.

The first and second sleeves 272, 274 are dielectric. Sleeve 272 is described with the understanding that sleeve 274 is identically formed.

The sleeve 272 is formed in two parts and includes an upper housing 221 and a lower housing 223. A push nut 225 is attached to the sleeve 272 to retain the sleeve 272 on the pin 276 as discussed herein. The upper housing 221 is formed of an upper cylindrical wall 227 and a lower cylindrical wall 229 which are integrally formed. The lower cylindrical wall 229 has an outer diameter which is less than the outer diameter of the upper cylindrical wall 227. A central passageway 231 extends through the upper and lower walls 227, 229 and has a diameter which is substantially the same diameter as the pin 276. The lower housing 223 is formed of a cylindrical wall 233 which has a central aperture therethrough which has a diameter which is substantially the same diameter as the pin 276. The push nut 225 is formed of a cylindrical wall 235 having a plurality of inwardly extending tangs 237. The tangs 237 can flex relative to each other and relative to the cylindrical wall 235 of the push nut 225. The tangs 237 do not extend completely to the center of the push nut 225, and instead a central aperture 239 is provided which has a diameter which is less than the diameter as the pin 276. A recess 245 is formed in the lower portion of the cylindrical wall 233 of the lower cap 223 which has the substantially the same dimensions as the push nut 225 so that the push nut 225 can be seated within the recess 245.

To assemble these components, the first and second leads 110, 114 of the LED device 20 are seated on top of the upper cap housings 221 such that the substrate 106 of the LED device 20 is between the upper housings 221. The apertures 112, 114 through the first and second leads 110, 114 are aligned with the central passageways 231 through the upper housings 221.

Next, the pins 276, 278 are inserted through the apertures 112, 116 in the first and second leads 110, 114 and through the central passageways 231 in the upper housings 221. The heads 280 of the pins 276, 278 bear against the top surfaces of the first and second leads 110, 114, but because the apertures 112, 116 through the first and second leads 110, 114 are smaller than the heads 280, the heads 280 do not pass through the first and second leads 110, 114. The knurled first section 282a of each pin 276, 278 engages with the first and second leads 110, 114 and the upper housings 221. The knurled first section 282a cuts a serrated pattern into the first and second leads 110, 114 which prevent the pins 276, 278 from rotating relative to the first and second leads 110, 114. In addition, the knurled first section 282a causes a hoop stress which results in an inwardly radial force to secure and stabilize the electrical connection between the pins 276, 278 and the first and second leads 110, 114. The knurled first section 282a also cuts a serrated pattern into each upper housing 221 which prevents the pins 276, 278 from rotating relative to the sleeves 272, 274, and secures the sleeves 272, 274 to the first and second leads 110, 114. If desired, the heads 280 of the pins 276, 278 and the leads 110, 114 can be soldered together to further secure the connection.

Next, a thermally conductive grease or adhesive to the upper surface of the base 32 of the heat sink 24 and to the upper surface of the top insulator 28 (if provided). The top insulator 28 would be attached to the sleeves 272, 274 by passing the respective lower cylindrical walls 229 through the apertures 98, 100 in the top insulator 28. Preferably, the shape of the apertures 98, 100 in the top insulator 28 would mirror the shape of the lower cylindrical walls 229 to prevent the top insulator 28 from moving relative to the sleeves 272, 274. As a result, the upper caps 227 abut the top surface of the top insulator 28. The top insulator 28 abuts against the slug 118 on the LED device 20. The thermally conductive grease or adhesive fills in surface irregularities to facilitate heat transfer between the heat sink 224 and the LED device 20 when they are assembled together.

The pins 276, 278 are then inserted into the gaps or channels 256, 270 between the respective electrical path retaining fins 240, 240′; 242, 242′. The ends of the pins 276, 278 are inserted through the apertures in the lower housings 223 and the lower housings 223 are slid upwardly along the second sections 282b of the pins 276, 278 until lower housings 223 abut the lower insulator 30 (if provided). The ends of the pins 276, 278 are inserted through the apertures 239 in the push nuts 225 and the push nuts 225 are upwardly along the second sections 282b of the pins 276, 278 until the push nuts 225 are seated within the recesses 245 in the lower housings 223. The tangs 237 flex as the push nuts 225 are slide along the pins 276, 278. If a user attempts to move the push nuts downwardly along the pins 276, 278, the tangs 237 bite into the second sections 282b of the pins 276, 278 to prevent downward movement.

A portion of each second section 282b of the pins 276, 278 extends downwardly from the heat sink 224. The second section 282b of each pin 276, 278 is passed through and extends from the respective aperture 102, 104 in the bottom insulator 30. The bottom insulator 30 abuts the lower end of the heat sink 224. The ends of the pins 276, 278 can be friction fit, or otherwise secured, to the power source or circuit member.

Therefore, an anode of the LED device 20 is formed by the first lead 110 and the first pin 276, and a cathode of the LED device 20 is formed by the second lead 114 and the second pin 278. The anode and the cathode are electrically isolated from each other by the top insulator 28 (if provided), the sleeves 272, 274 and the bottom insulator 30 (if provided). The air gap surrounding the pins 276, 278 in the gaps or channels 256, 270 provides electrical isolation between the heat sink 224 and the pins 276, 278. This provides for an electrical path between the power source or circuit member and the LED device 20. As a result, a heat sink function and an electrical path retaining function are provided. During operation of the LED device 20, the LED device 20 generates heat which is transferred to the base 232 and to the fins 234, 240, 240′, 242, 242′, and this heat must be removed. As air is circulated around the base 232 by known means, the heat is removed.

In this second embodiment, additional components compared to the first embodiment are required, but the advantage is that less plastic material is needed. Furthermore, as the heat sink 224 becomes thinner, the upper and/or lower housings 221, 223 may extend substantially all the way through the heat sink 224 so as provide complete insulation. However, for certain applications an air gap may provide sufficient voltage separation.

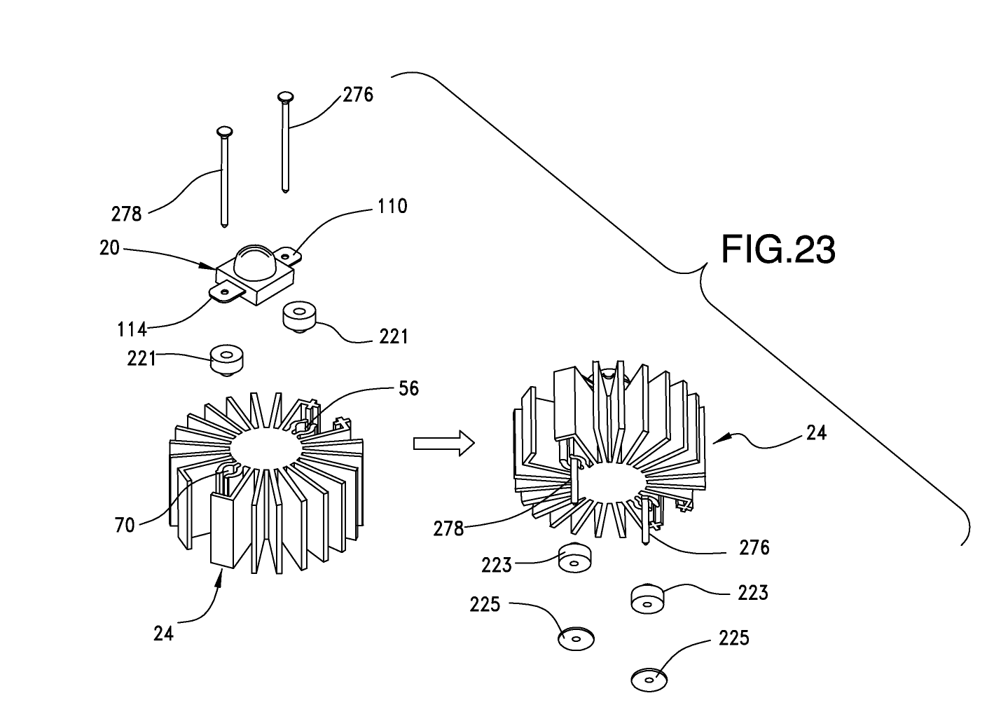

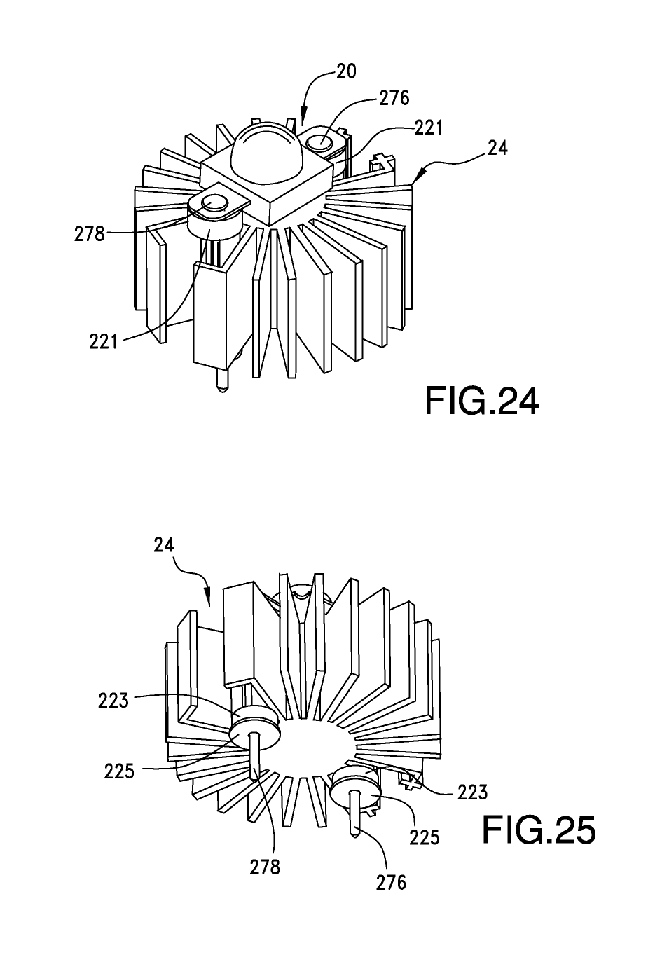

FIGS. 23-25 show how the electrical path assembly 226 and pins 276, 278 of the second embodiment can be used with the heat sink 24 of the first embodiment. In this embodiment, the pins 276, 278 (which may or may not have the knurled first sections 282a; if the pins 276, 278 are not knurled, then solder is used to attach the pins 276, 278 to the leads 110, 114) are then inserted into the gaps or channels 56, 70 between the respective electrical path retaining fins 40, 40′; 42, 42′. The ends of the pins 276, 278 are inserted through the apertures in the lower housings 223 and the lower housings 223 are slid upwardly along the second sections 282b of the pins 276, 278 until lower housings 223 abut the lower insulator 30 (if provided). The ends of the pins 276, 278 are inserted through the apertures 239 in the push nuts 225 and the push nuts 225 are upwardly along the second sections 282b of the pins 276, 278 until the push nuts 225 are seated within the recesses 245 in the lower housings 223. The tangs 237 flex as the push nuts 225 are slide along the pins 276, 278. If a user attempts to move the push nuts downwardly along the pins 276, 278, the tangs 237 bite into the second sections 282b of the pins 276, 278 to prevent downward movement. A portion of each second section 282b of the pins 276, 278 extends downwardly from the heat sink 24. The second section 282b of each pin 276, 278 is passed through and extends from the respective aperture 102, 104 in the bottom insulator 30. The bottom insulator 30 abuts the lower end of the heat sink 24. The ends of the pins 276, 278 can be friction fit, or otherwise secured, to the power source or circuit member.

In the embodiments shown in FIGS. 1-25, the pins 76, 78, 276, 278 may be plated or un-plated copper alloy, or zinc plated steel. For the embodiments shown in FIGS. 19-25, the push nuts 225 can be zinc plated steel. In the embodiments shown in FIGS. 1-25, it should also be noted that while the depicted sleeves 72, 74, 272, 274 are shaped the same on the anode and cathode, the sleeves 72, 72, 272, 274 may be modified to ensure the leads 110, 114 can only be inserted in a particular orientation. Similarly, the pins 76, 78, 276, 278 (as well as the LED device 20) may also be configured for a single orientation.

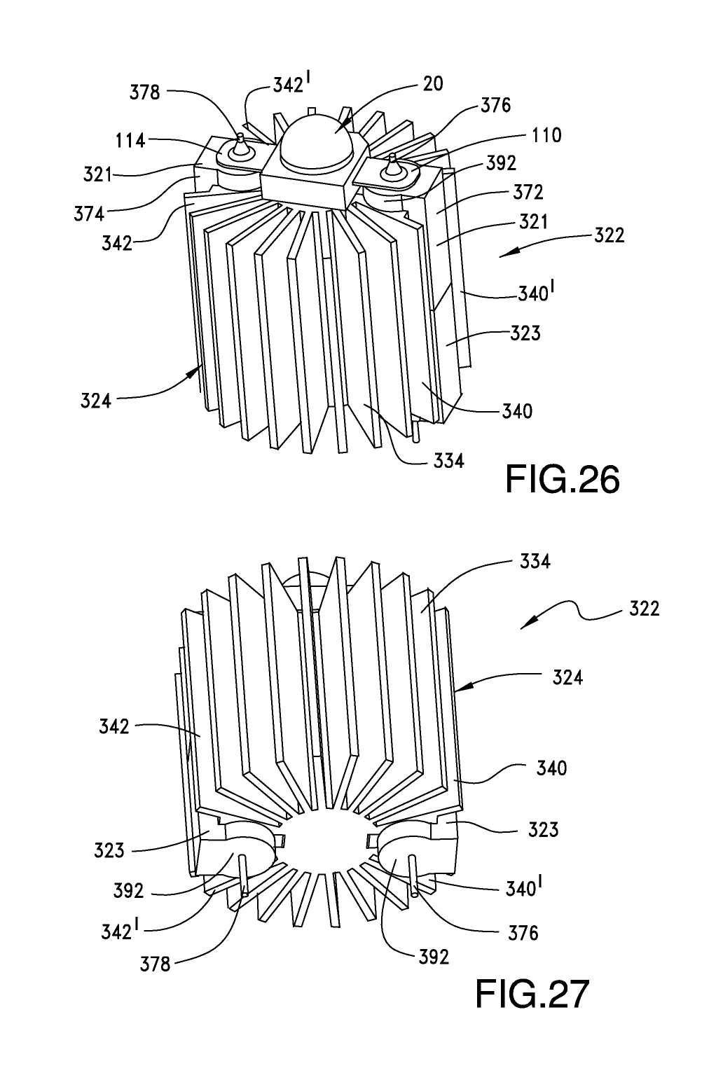

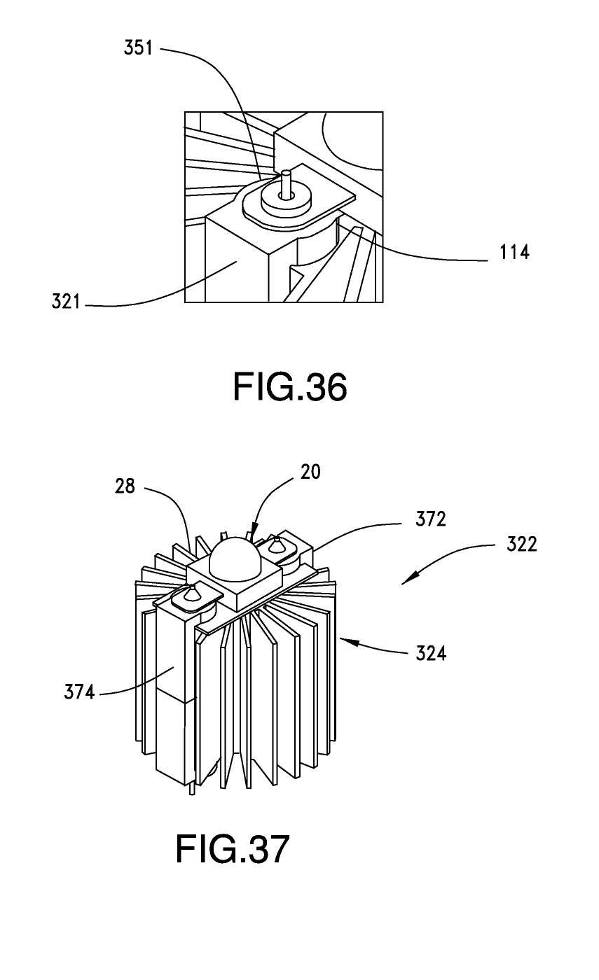

Attention is invited to the third embodiment of an assembly 322 shown in FIGS. 26-37. The assembly includes the LED device 20, a heat sink 324 and an electrical path assembly 326. Although a top insulator 28 and a bottom insulator 30 are not shown, they may be used in this third embodiment in the same manner as that provided in the first embodiment. The LED device 20 as shown is identical to that shown in the first embodiment. Therefore, the specifics of the LED device 20 are not repeated.

As best shown in FIG. 29, the heat sink 324 includes a base 332 having a plurality of spaced apart fins 334 extending from the exterior of the base 332, a first pair of electrical path retaining fins 340, 340′ extending from the exterior of the base 332, and a second pair of electrical path retaining fins 342, 342′ extending from the exterior of the base 332. The heat sink 324 is conventionally made of extruded aluminum and provides surface area for heat dissipation from the LED device 20.

The exterior of the base 332 is generally cylindrical. The top surface and the bottom surface of the base 332 are generally planar.

The first pair of electrical path retaining fins 340, 340′ include a first fin 340 and a second fin 340′ which are spaced apart from each other such that a channel 341 is defined therebetween. The first fin 340 has first section 348a which extends generally radially outwardly from the base 332, a second section 348b which has an inner surface that is arcuate and an outer surface that extends generally radially outwardly from the base 332, and a third section 348c which extends generally radially outwardly relative to the base 332. The second fin 340′ has first section 350a which extends generally radially outwardly from the base 332, a second section 350b which has an inner surface that is arcuate and an outer surface that extends generally radially outwardly from the base 332, and a third section 350c which extends generally radially outwardly relative to the base 332. The first sections 348a, 350a are spaced apart from each other to form a pocket 352 of the channel 341. The third sections 348c, 350c are spaced apart from each other to form a slot 354 of the channel 341. The area between the arcuate inner surfaces of the second sections 348b, 350b form a gap 356 of the channel 341. Each fin 340, 340′ extends from the top end to the bottom end of the base 332.

The second pair of electrical path retaining fins 342, 342′ include a first fin 342 and a second fin 342′ which are spaced apart from each other such that a channel 343 is defined therebetween. The first fin 342 has first section 362a which extends generally radially outwardly from the base 332, a second section 362b which has an inner surface that is arcuate and an outer surface that extends generally radially outwardly from the base 332, and a third section 362c which extends generally radially outwardly relative to the base 332. The second fin 342′ has first section 364a which extends generally radially outwardly from the base 332, a second section 364b which has an inner surface that is arcuate and an outer surface that extends generally radially outwardly from the base 332, and a third section 364c which extends generally radially outwardly relative to the base 332. The first sections 362a, 364a are spaced apart from each other to form a pocket 366 of the channel 343. The third sections 262c, 264c are spaced apart from each other to form a slot 368 of the channel 343. The area between the arcuate inner surfaces of the second sections 262b, 264b form a gap 370 of the channel 343. Each fin 342, 342′ extends from the top end to the bottom end of the base 332.

A plurality of the fins 334 are provided at spaced apart locations along the exterior of the base 332 between the first and second pairs of electrical path retaining fins 340, 340′; 342, 342′. Each fin 334 extends radially outwardly from the base 332 and extends from the top end to the bottom end of the base 332.

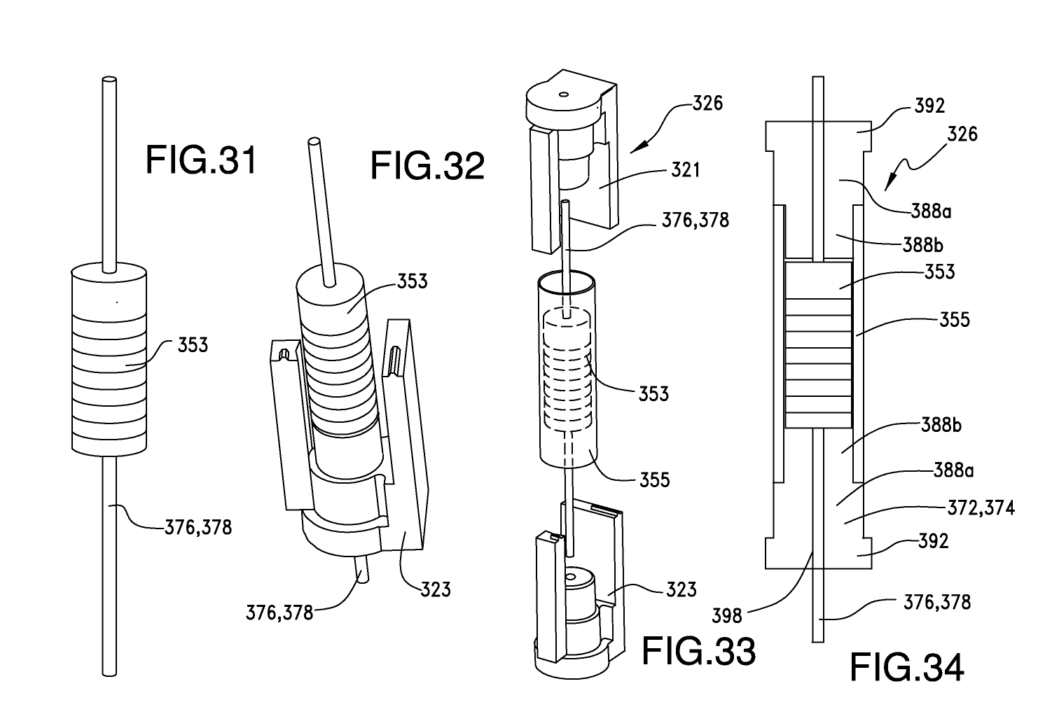

The electrical path assembly 326 is used to connect the LED device 20 to the power source or circuit member (not shown) and is best shown in FIGS. 31-34. The electrical path assembly 326 includes first and second sleeves 372, 374 and first and second pins 376, 378. The sleeves 372, 374 are mounted within the channels 341, 343 as described herein.

Each pin 376, 378 is electrically conductive and includes an elongated cylindrical shank 382. A resistor 353 is mounted on the shank 382 of each pin 376, 378. An insulating tube 355 surrounds the resistor 353.

The first and second sleeves 372, 374 are dielectric. Sleeve 372 is described with the understanding that sleeve 374 is identically formed.

The sleeve 372 is formed from two hermaphroditic housing, including an upper housing 321 and a lower housing 323 which are mated together and surround the resistor 353. Since the housings 321, 323 are hermaphroditic, only lower housing 323 is described with the understanding that the upper housing 321 is identically formed.

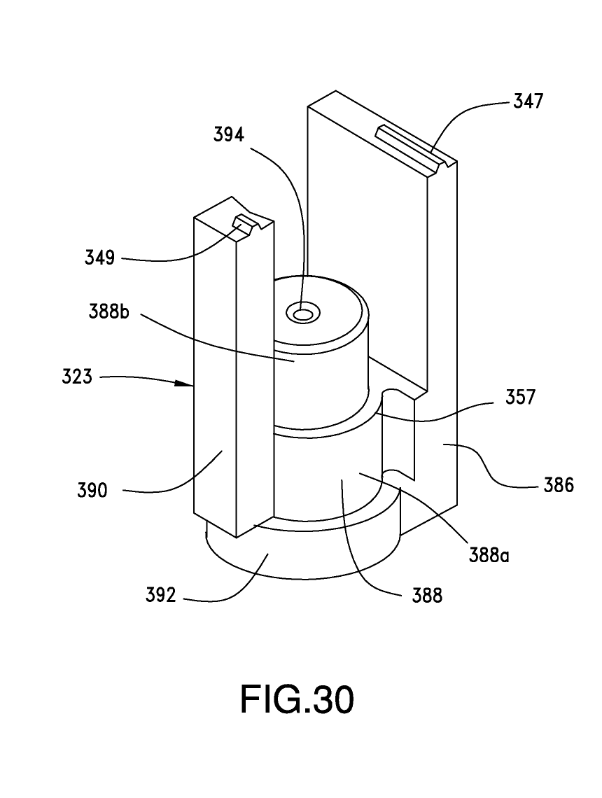

As best shown in FIG. 30, the housing 323 has an elongated base wall 386, an elongated tubular wall 388 extending from the base wall 386, an elongated finger wall 390 extending outwardly from the tubular wall 388, and a cap 392 provided at an end of the walls 386, 388, 390. The components of the housing 323 are integrally formed and may be molded.

The base wall 386 is generally rectangular in shape. An energy director 347, which takes the form of an elongated raised rib, is provided on an upper end of the base wall 386. The energy director 347 does not extend the entire width of the base wall 386. The width of the base wall 386 is slightly less than the slot 354, 368 provided between the electrical path retaining fins 340, 340′; 342, 342′.

The cap 392 is generally cylindrical and has an aperture 398 provided therethrough. The aperture 398 has substantially the same diameter as the shanks 382 of the pins 376, 378. The cap 398 extends perpendicularly from the base wall 386 at the lower end thereof.

The tubular wall 388 has a central passageway 394 therethrough which has substantially the same diameter as the shanks 382 of the pins 376, 378 and the aperture 398. The exterior surface of the tubular wall 388 is stepped to form a lower cylindrical section 388a and an upper cylindrical section 388b. The diameter of the lower cylindrical section 388a is less than the diameter of the cap 392. The diameter of the upper cylindrical section 388b is less than the diameter of the lower cylindrical section 388a, such that a shoulder 357 is formed between the lower and upper cylindrical sections 388a, 388b. Preferably, the lower and upper cylindrical sections 388a, 388b of the tubular wall 388 are cylindrical, but they are is not limited to this shape, provided the gaps 356, 370 mirror the shape of lower section 388a. The tubular wall 388 extends upwardly from the cap 392. The tubular wall 388 extends from the interior surface of the base wall 386. The tubular wall 388 extends part of the way along the height of the base wall 386, such that the tubular wall 388 terminates at a point which is spaced from the upper end of the base wall 386. Like the tubular wall 388, the cap 392 is not limited to a cylindrical shape.

The finger wall 390 is generally rectangular in shape and extends from the diametrically opposed side of the tubular wall 388 to that from which the base wall 386 extends. An energy director 349, which takes the form of an elongated raised rib, is provided on an upper end of the finger wall 390. The energy director 349 does not extend the entire width of the finger wall 390. The dimensions of the finger wall 390 are slightly less than the pocket 352, 366 provided between the electrical path retaining fins 340, 340′; 342, 342′.

The sleeves 372, 374 and pins 376, 378 are assembled with the heat sink 324 prior to the attachment of the LED device 20 to the electrical path assembly 326. The assembly of sleeve 372 and pin 376 to the heat sink 324 is described with the understanding that the assembly of sleeve 374 and pin 378 are assembled with the heat sink 324 in the identical manner.

As shown in FIG. 31, the resistor 353 is mounted on the pin 376. Thereafter, the pin 376 is inserted into the insulating tube 355 until the insulating tube 355 surrounds the resistor 353. The insulating tube 355 is longer than the resistor 353. Next, the pin 376 is assembled with the lower housing 323. The lower end of the pin 376 is inserted through the central passageway 394 in the tubular wall 388 and through the aperture 398 in the cap 392 such that the end of the pin 376 extends downwardly from the lower housing 323 a predetermined distance. The end of the resistor 353 sits against the upper end of the second section 388b of the tubular wall 388 and the end of the insulating tube 355 which extends beyond the resistor 353 surrounds the second section 388b. The end of the insulating tube 355 sits against the shoulder 357. The upper end of the pin 376 is then inserted into the end of the gap 356 between the electrical path retaining fins 340, 340′ and pushed upwardly. The finger wall 390 slides within the pocket 352, the second section 388b of the tubular wall 388 slides within the gap 356, and the base wall 386 slides within the slot 354 until the cap 392 abuts against the bottom surface of the electrical path retaining fins 340, 340′. The end of the pin 376 extends downwardly from the heat sink 324 a predetermined distance. The upper housing 321 is then attached to the pin 376 and slid into the heat sink 324. The finger wall 390 slides within the pocket 352, the second section 388b of the tubular wall 388 slides within the gap 356, and the base wall 386 slides within the slot 354. When the upper housing 321 is sufficiently inserted into the heat sink 324, the pin 376 will engage into the aperture 394 in the tubular wall 388. The upper housing 321 is continued to be slid into the heat sink 324, until the cap 392 abuts against the upper surface of the electrical path retaining fins 340, 340′. The end of the pin 376 is inserted through the central passageway 394 in the tubular wall 388 and through the aperture 398 in the cap 392 such that the end of the pin 376 extends upwardly from the heat sink 324 a predetermined distance. The end of the resistor 353 sits against the lower end of the second section 388b of the tubular wall 388 and the end of the insulating tube 355 which extends beyond the resistor 353 surrounds the second section 388b. The end of the insulating tube 355 sits against the shoulder 357.

As a result, the lower end of the base wall 388 of each upper housing 321 abuts against the upper end of the base wall 388 of each lower housing 321, and the lower end of the finger wall 390 of each upper housing 321 abuts against the upper end of the finger wall 390 of each lower housing 321. Thereafter, the energy directors 347, 349 are subjected to ultrasound to ultrasonically weld the upper and lower housings 321, 323 together. It is within the scope of the invention that other means are used for joining the upper and lower housings 321, 323 together.

While the assembly is described with the lower housings 323 first being assembled with the pins 376, 378, it is clear that instead the upper housing 321 could first be assembled with the pins 376, 378 and first inserted into the heat sink 324. Thereafter, the lower housing 323 would be assembled with the heat sink 324.

Because the base wall 388 and the finger wall 390 do not completely surround the resistor 353, an air gap is provided around a portion of the resistor 353. The heat generated by the resistor 353 is therefore transferred to the heat sink 324.

The amount of insulation value can be adjusted by increasing the diameter of the cap 392.

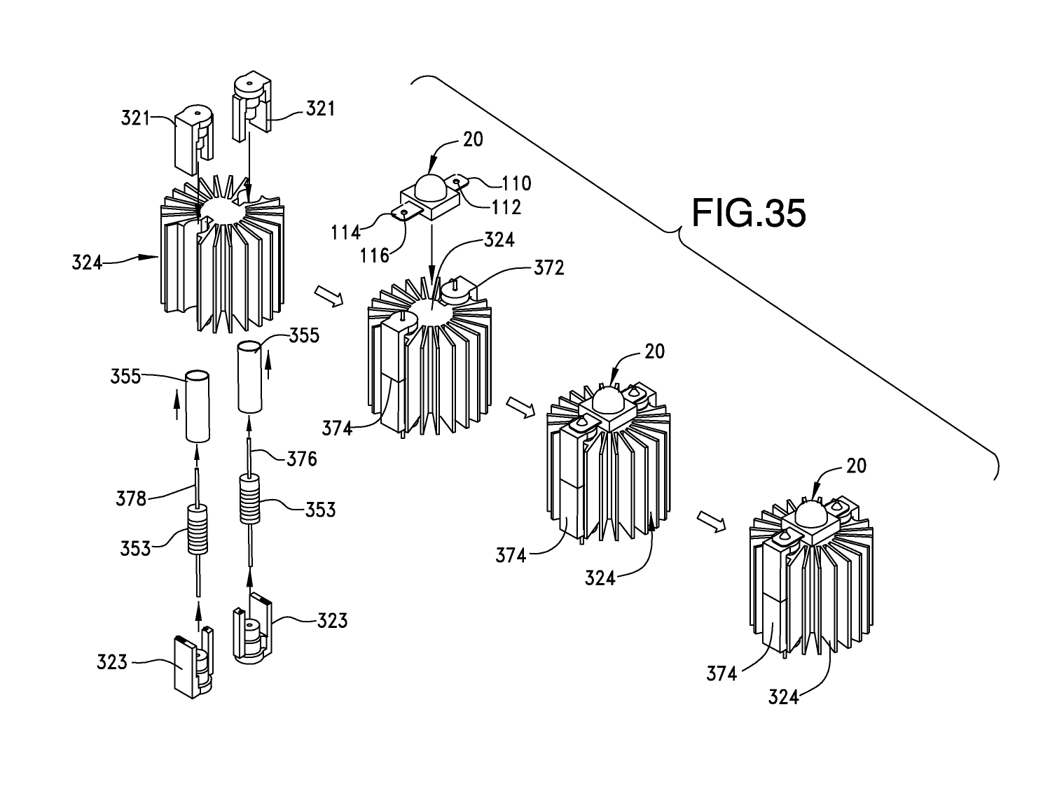

The assembly of the electrical path assembly 326 with the LED device 20 is shown in FIG. 35. To assemble these components, the pins 376, 378 are inserted through the apertures 112, 114 of the leads 110, 114 of the LED device 20 until the first and second leads 110, 114 are seated on top of the upper housings 321, the substrate 106 of the LED device 20 is between the upper housings 321 and the slug 118 abuts against the upper surface of the base 332. The pins 376, 378 and leads 110, 114 are then soldered together to form the connection. A solder pre-formed 351 can be placed on top of the leads 110, 114 to effect the soldering, however, hand-soldering or other suitable soldering means can be used.

A thermally conductive grease or adhesive can be applied to the upper surface of the base 332 of the heat sink 324 and to the upper surface of the top insulator 28, if one is used as shown in FIG. 37. The top insulator 28 can have cutouts in the shape of the caps 392 to accommodate the caps 392 therein. Preferably, the shape of the apertures 98, 100 in the top insulator 28 would mirror the shape of the caps 392 to prevent the top insulator 28 from moving relative to the sleeves 372, 374. As a result, the caps 392 abut the top surface of the top insulator 28. The top insulator 28 abuts against the slug 118 on the LED device 20. The thermally conductive grease or adhesive fills in surface irregularities to facilitate heat transfer between the heat sink 224 and the LED device 20 when they are assembled together.

Therefore, an anode of the LED device 20 is formed by the first lead 110 and the first pin 376, and a cathode of the LED device 20 is formed by the second lead 114 and the second pin 378. The anode and the cathode are electrically isolated from each other by the top insulator 28 (if provided), the sleeves 372, 374 and the bottom insulator 30 (if provided). The air gap surrounding the pins 376, 378 in the gaps 356, 370 provides electrical isolation between the heat sink 324 and the pins 376, 378. This provides for an electrical path between the power source or circuit member and the LED device 20. As a result, a heat sink function and an electrical path retaining function are provided. During operation of the LED device 20, the LED device 20 generates heat which is transferred to the base 332, 334, 340, 340′, 342, 342′, and this heat must be removed. As air is circulated around the base 332 by known means, the heat is removed.

It is to be understood that the tip of each pins 376, 378 may have a solder tip provided thereon as shown in the first and second embodiment, or each tip may take other forms as shown in FIGS. 18A-18D.

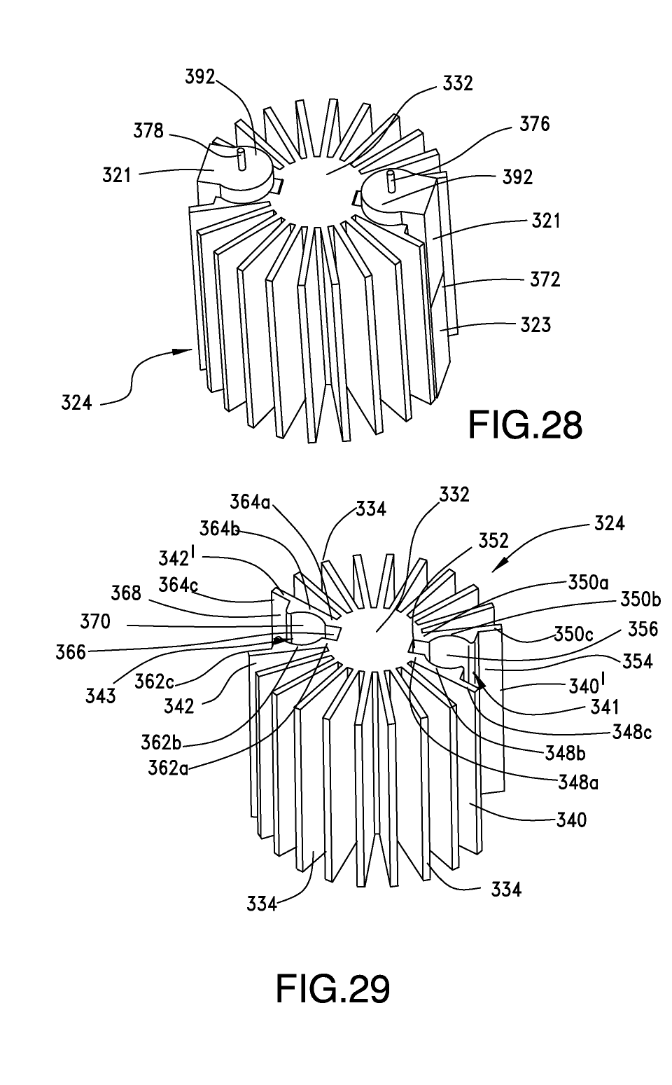

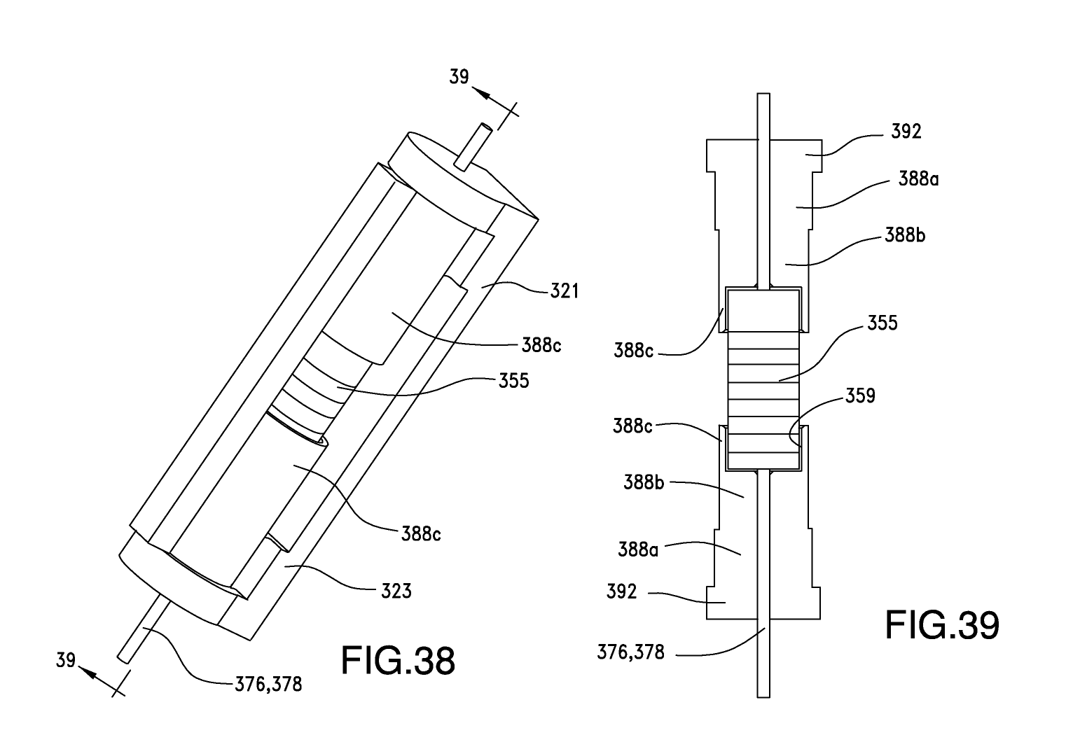

FIGS. 38 and 39 shows an alternate configuration for the sleeves 372, 374 which are used to eliminate the insulating tube 355. The sleeves 372, 374 shown in FIG. 28 are identical to sleeve 372, 374 of the third embodiment shown in FIGS. 26-37, with the exception of an addition of a skirt 388c attached to the end of the second section 388b of the tubular wall 388. Therefore, only the differences are described. Sleeve 372 is described with the understanding that sleeve 374 is identically formed. The skirt 388c extends upwardly from the second section 388b and defines a recess 359 in which the resistor 353 is partially seated.

The sleeves 372, 374 and pins 376, 378 are assembled with the heat sink 324 prior to the attachment of the LED device 20 to the electrical path assembly 326. The assembly of sleeve 372 and pin 376 to the heat sink 324 is described with the understanding that the assembly of sleeve 374 and pin 378 are assembled with the heat sink 324 in the identical manner.

The resistor 353 is mounted on the pin 376. Thereafter, the pin 376 is assembled with the lower housing 323. The lower end of the pin 376 is inserted through the central passageway 394 in the tubular wall 388 and through the aperture 398 in the cap 392 such that the end of the pin 376 extends downwardly from the lower housing 323 a predetermined distance. The lower end portion of the resistor 353 sits within the recess 359 of the skirt 388c and the lower end of the resistor 353 abuts against the upper end of the second section 388b of the tubular wall 388. The upper end of the pin 376 is then inserted into the end of the gap 356 between the electrical path retaining fins 340, 340′ and pushed upwardly. The finger wall 390 slides within the pocket 352, the second section 388b of the tubular wall 388 slides within the gap 356, and the base wall 386 slides within the slot 354 until the cap 392 abuts against the bottom surface of the electrical path retaining fins 340, 340′. The end of the pin 376 extends downwardly from the heat sink 324 a predetermined distance. The upper housing 321 is then attached to the pin 376 and slid into the heat sink 324. The finger wall 390 slides within the pocket 352, the second section 388b of the tubular wall 388 slides within the gap 356, and the base wall 386 slides within the slot 354. When the upper housing 321 is sufficiently inserted into the heat sink 324, the pin 376 will engage into the aperture 394 in the tubular wall 388. The upper housing 321 is continued to be slid into the heat sink 324, until the cap 392 abuts against the upper surface of the electrical path retaining fins 340, 340′. The end of the pin 376 is inserted through the central passageway 394 in the tubular wall 388 and through the aperture 398 in the cap 392 such that the end of the pin 376 extends upwardly from the heat sink 324 a predetermined distance. The upper end portion of the resistor 353 sits within the recess 359 of the skirt 388c and the upper end of the resistor 353 abuts against the lower end of the second section 388b of the tubular wall 388.

While the assembly is described with the lower housings 323 first being assembled with the pins 376, 378, it is clear that instead the upper housing 321 could first be assembled with the pins 376, 378 and first inserted into the heat sink 324. Thereafter, the lower housing 323 would be assembled with the heat sink 324.

Because the base wall 388, the tubular wall 388 and the finger wall 390 do not completely surround the resistor 353, an air gap is provided around a portion of the resistor 353. The heat generated by the resistor 353 is therefore transferred to the heat sink 324.

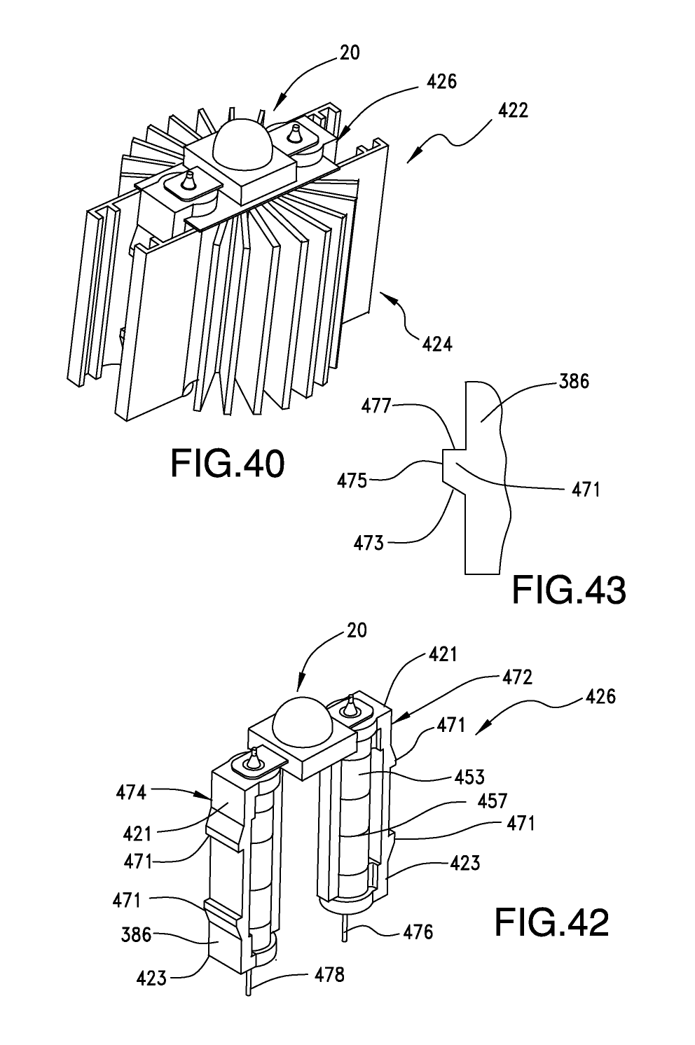

Attention is invited to the fourth embodiment of an assembly 422 shown in FIGS. 40-42. The assembly includes the LED device 20, a heat sink 424 and an electrical path assembly 426. Although a top insulator 28 and a bottom insulator 30 are not shown, they may be used in this fourth embodiment in the same manner as that provided in the first embodiment. The LED device 20 as shown is identical to that shown in the first embodiment. Therefore, the specifics of the LED device 20 are not repeated.

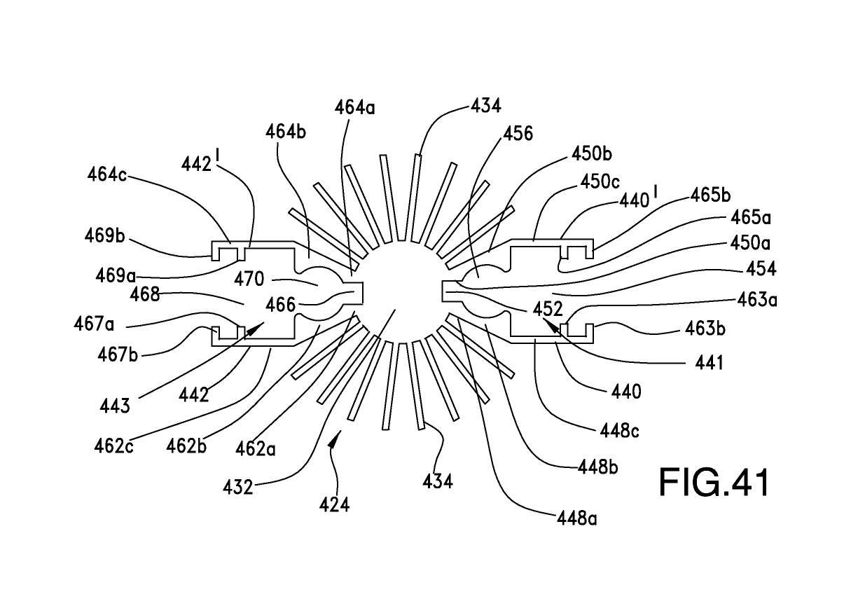

As best shown in FIG. 41, the heat sink 424 includes a base 432 having a plurality of spaced apart fins 434 extending from the exterior of the base 432, a first pair of electrical path retaining fins 440, 440′ extending from the exterior of the base 432, and a second pair of electrical path retaining fins 442, 442′ extending from the exterior of the base 432. The heat sink 424 is conventionally made of extruded aluminum and provides surface area for heat dissipation from the LED device 20.

The exterior of the base 432 is generally cylindrical. The top surface and the bottom surface of the base 432 are generally planar.

The first pair of electrical path retaining fins 440, 440′ include a first fin 440 and a second fin 440′ which are spaced apart from each other such that a channel 441 is defined therebetween. The first fin 440 has first section 448a which extends generally radially outwardly from the base 432, a second section 448b which has an inner surface that is arcuate and an outer surface that extends generally radially outwardly from the base 432, and a third section 448c which extends at an angle relative to the first section 448a and the outer surface of the second section 448b. The second fin 440′ has first section 450a which extends generally radially outwardly from the base 432, a second section 450b which has an inner surface that is arcuate and an outer surface that extends generally radially outwardly from the base 432, and a third section 450c which extends at an angle relative to the first section 450a and the outer surface of the second section 450b. The first sections 448a, 450a are spaced apart from each other to form a pocket 452 of the channel 441. The third sections 448c, 450c are spaced apart from each other, and are parallel to each other. The third sections 448c, 450c define a slot 454 of the channel 441 therebetween. The third section 448c includes a pair of spaced apart protrusions 463a, 463b at the free end thereof, and the third section 450c includes a pair of spaced apart protrusions 465a, 465b at the free end thereof. The protrusions 463a, 465a are aligned with each other and extend into the slot 454 a predetermined distance. The protrusions 463b, 465b are aligned with each other and extend into the slot 454 a predetermined distance. The protrusions 463a, 463b; 465a, 465b extend the full height of the respective thirds sections 448c, 450c. The area between the inner arcuate surfaces of the second sections 448b, 450b form a gap 456 of the channel 441. Each fin 440, 440′ extends from the top end to the bottom end of the base 432.

The second pair of electrical path retaining fins 442, 442′ include a first fin 442 and a second fin 442′ which are spaced apart from each other such that a channel 443 is defined therebetween. The first fin 442 has first section 462a which extends generally radially outwardly from the base 432, a second section 462b which has an inner surface that is arcuate and an outer surface that extends generally radially outwardly from the base 432, and a third section 462c which extends at an angle relative to the first section 462a and the outer surface of the second section 462b. The second fin 442′ has first section 464a which extends generally radially outwardly from the base 432, a second section 464b which has an inner surface that is arcuate and an outer surface that extends generally radially outwardly from the base 432, and a third section 464c which extends at an angle relative to the first section 464a and the outer surface of the second section 464b. The first sections 462a, 464a are spaced apart from each other to form a pocket 466 of the channel 443. The third sections 462c, 464c are spaced apart from each other, and are parallel to each other. The third sections 462c, 462c define a slot 468 of the channel 443 therebetween. The third section 462c includes a pair of spaced apart protrusions 467a, 467b at the free end thereof, and the third section 464c includes a pair of spaced apart protrusions 469a, 469b at the free end thereof. The protrusions 467a, 469a are aligned with each other and extend into the slot 468 a predetermined distance. The protrusions 467b, 469b are aligned with each other and extend into the slot 468 a predetermined distance. The protrusions 467a, 467b; 469a, 469b extend the full height of the respective thirds sections 462c, 464c. The area between the inner arcuate surfaces of the second sections 462b, 464b form a gap 470 of the channel 443. Each fin 442, 442′ extends from the top end to the bottom end of the base 432.

A plurality of the fins 434 are provided at spaced apart locations along the exterior of the base 432 between the first and second pairs of electrical path retaining fins 440, 440′; 442, 442′. Each fin 434 extends radially outwardly from the base 432 and extends from the top end to the bottom end of the base 432.

The electrical path assembly 426 is used to connect the LED device 20 to a power source or circuit member (not shown) and is best shown in FIG. 42. The electrical path assembly 426 includes first and second sleeves 472, 474 and first and second pins 476, 478. The sleeves 472, 474 are mounted within the channels 441, 443 as described herein.

Each pin 476, 478 is electrically conductive and includes an elongated cylindrical shank. A resistor 453 is mounted on the shank 382 of each pin 376, 378. A tube 457 can be provided to surround the resistor 453.

The first and second sleeves 472, 474 are dielectric. Sleeve 472 is described with the understanding that sleeve 474 can be identically formed.

The sleeve 472 is formed from two hermaphroditic housing, including an upper housing 421 and a lower housing 423 which are mated together and surround the resistor 453. Since the housings 421, 423 are hermaphroditic, only lower housing 423 is described with the understanding that the upper housing 421 is identically formed.

Lower housing 423 is identical to the lower housing 323 of the third embodiment with the exception that an elongated locking nub 471 is provided on the base wall 386. Therefore, the other specifics of the lower housing 423 are not described herein, but identical reference numbers to that used in the third embodiment are provided to denote like elements. The locking nub 471 is spaced from the bottom end of the base wall 486. The locking nub 471 includes a lower surface 473 which angles upwardly and outwardly from the base wall 386, an outer surface 475 which is parallel to the base wall 386 and is connected to the outermost end of the lower surface 473, and a top surface 477 which is perpendicular to the outer surface 475 and to the base wall 386.

The sleeves 472, 474 and pins 476, 478 are assembled with the heat sink 424 prior to the attachment of the LED device 20 to the electrical path assembly 426. The assembly of sleeve 472 and pin 476 to the heat sink 424 is described with the understanding that the assembly of sleeve 474 and pin 478 are assembled with the heat sink 424 in the identical manner.

The resistor 453 is mounted on the pin 476. Thereafter, the pin 476 is inserted into the tube 457 (which may be an insulating material and/or may have a thermal resistivity much lower than the corresponding sleeve) until the tube 457 surrounds the resistor 453. The tube 457 is longer than the resistor 453. Next, the pin 476 is assembled with the lower housing 423. The lower end of the pin 476 is inserted through the central passageway 394 in the tubular wall 388 and through the aperture 398 in the cap 392 such that the end of the pin 476 extends downwardly from the lower housing 423 a predetermined distance. The end of the resistor 453 sits against the upper end of the second section 388b of the tubular wall 388 and the end of the tube 457 which extends beyond the resistor 453 surrounds the second section 388b. The end of the insulating tube 455 sits against the shoulder 357. The upper end of the pin 476 is then inserted into the end of the gap 456 between the electrical path retaining fins 440, 440′ and pushed upwardly. The finger wall 390 slides within the pocket 452, the second section 388b of the tubular wall 388 slides within the gap 456, and the base wall 386 slides within the slot 454 until the cap 392 abuts against the bottom surface of the electrical path retaining fins 440, 440′. The base wall 386 does not completely fill the slot 454. The end of the pin 476 extends downwardly from the heat sink 424 a predetermined distance. The upper housing 421 is then attached to the pin 476 and slid into the heat sink 424. The finger wall 390 slides within the pocket 452, the second section 388b of the tubular wall 388 slides within the gap 456, and the base wall 486 slides within the slot 454. The base wall 386 does not completely fill slot 454. When the upper housing 421 is sufficiently inserted into the heat sink 424, the pin 476 will engage into the aperture 394 in the tubular wall 388. The upper housing 421 is continued to be slid into the heat sink 424, until the cap 392 abuts against the upper surface of the electrical path retaining fins 440, 440′. The end of the pin 476 is inserted through the central passageway 394 in the tubular wall 388 and through the aperture 398 in the cap 392 such that the end of the pin 476 extends upwardly from the heat sink 424 a predetermined distance. The end of the resistor 453 sits against the lower end of the second section 388b of the tubular wall 388 and the end of the tube 457 which extends beyond the resistor 453 surrounds the second section 388b. The end of the tube 457 sits against the shoulder 357.

As a result, the lower end of the base wall 388 of each upper housing 421 abuts against the upper end of the base wall 388 of each lower housing 421, and the lower end of the finger wall 390 of each upper housing 421 abuts against the upper end of the finger wall 390 of each lower housing 421. Thereafter, the energy directors 347, 349 are subjected to ultrasound to ultrasonically weld the upper and lower housings 421, 423 together. It is within the scope of the invention that other means are used for joining the upper and lower housings 421, 423 together.

While the assembly is described with the lower housings 423 first being assembled with the pins 476, 478, it is clear that instead the upper housing 421 could first be assembled with the pins 476, 478 and first inserted into the heat sink 424. Thereafter, the lower housing 423 would be assembled with the heat sink 424.

Because the base wall 388 and the finger wall 390 do not completely surround the resistor 453, an air gap is provided around a portion of the resistor 453. The heat generated by the resistor 453 is therefore transferred to the heat sink 424.

The assembly of the electrical path assembly 426 with the LED device 20 is identical to that shown in the third embodiment. Therefore, the specifics are not repeated herein.

The shanks of the pins 476, 478 can be of varying lengths and can be formed in suitable ways. In addition, it is to be understood that the tip of each pins 476, 478 may have a solder tip provided thereon as shown in the first and second embodiment, or each tip may take other forms as shown in FIGS. 18A-18D. Also, it is to be understood that the alternate configuration for the sleeves 372, 374 shown in FIGS. 38 and 39 could be used and provided with locking nubs 471 thereon.

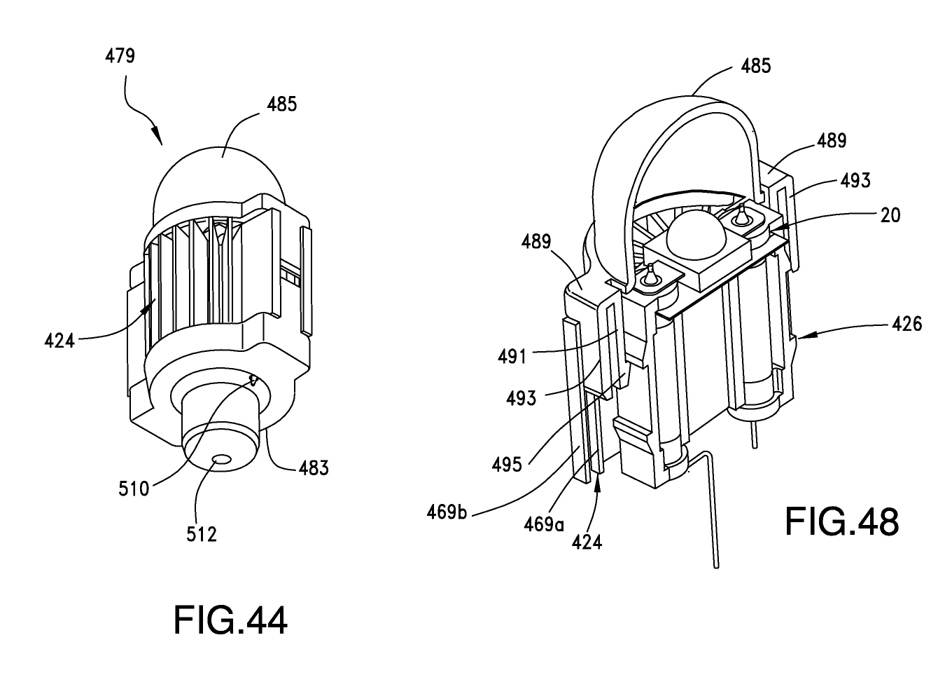

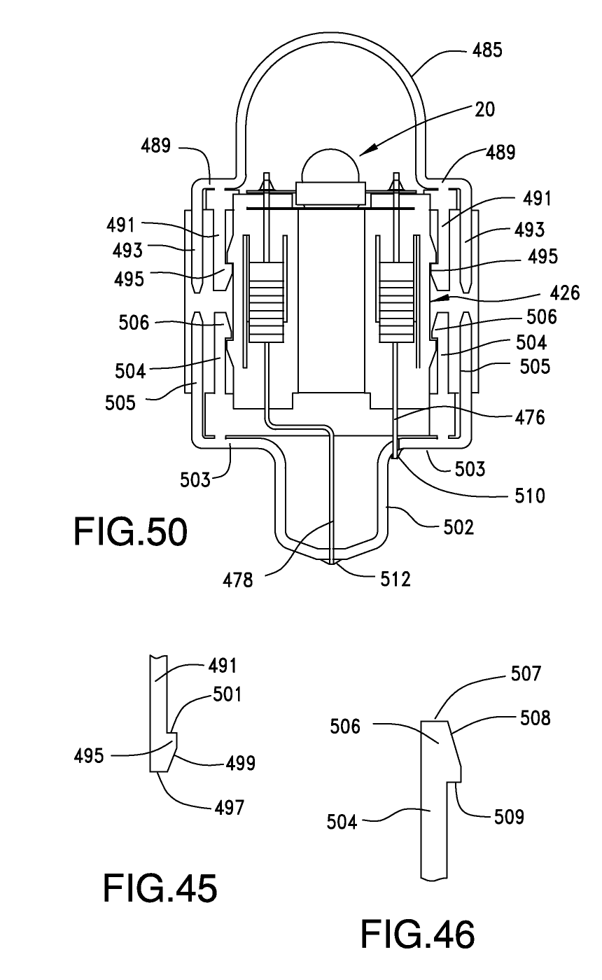

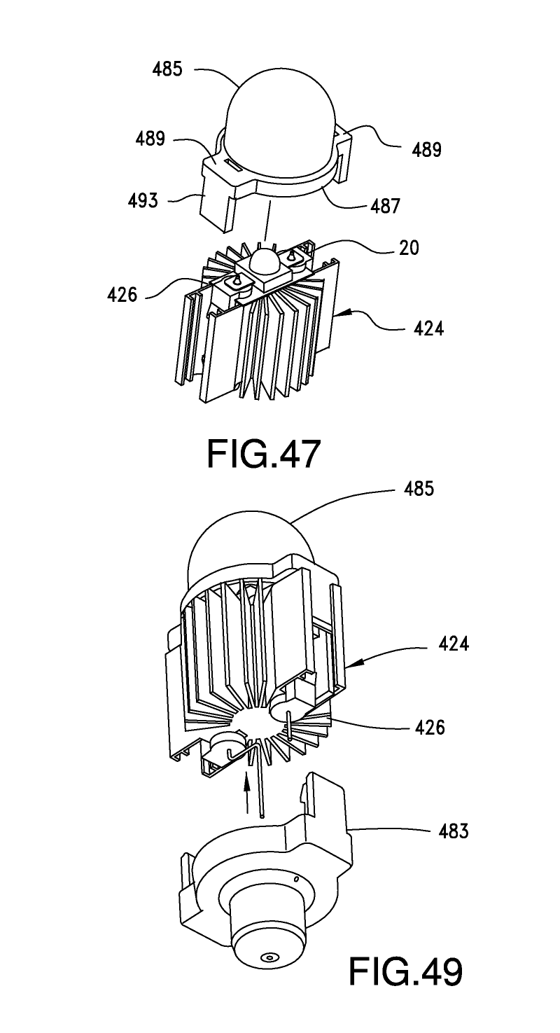

The assembled LED device 20, heat sink 424 and electrical path assembly 426 can be attached to an associated circuit board (not shown) in the configuration shown in FIG. 40. As shown in FIGS. 44-50, the assembled LED device 20, heat sink 424 and electrical path assembly 426 are incorporated into a lightbulb assembly 479. The lightbulb assembly 479 adds lens 481 and a base 483 (which may be an Edison-type base as depicted) so that the lightbulb assembly 479 can be attached to a socket.

The lens 481 includes a dome 485 having a base wall 487 extending around the perimeter of the dome 485. A wall 489 extends outwardly from each side of the base wall 487 at diametrically-opposed sides thereof. A pair of spaced apart legs 491, 493 depend downwardly from the underside of the wall 489. Each leg 491, 493 is generally rectangular, except leg 491 has a locking nub 495 thereon which extends outwardly therefrom in a direction which is away from the leg 493. The locking nub 495 includes a lower surface 497 which is perpendicular to the surfaces of the leg 491, an inner surface 499 which angles upwardly and outwardly from the leg 491, and a top surface 501 which is perpendicular to the surfaces of the leg 491. The lens 481 is made of clear or translucent material. The lens 481 can made of materials which have the ability to diffuse light, filter light, polarize light, or that have other optical characteristics.

The lens 481 is snapped onto the electrical path assembly 426 using the locking nubs 471, 495. The legs 491, 493 of the lens 481 are inserted into the respective slots 454, 468 of the heat sink 424. On one side of the lens 481, leg 493 seats between protrusions 463a, 465a and protrusions 463b, 465b; on the other side of the lens 481, the other leg 493 seats between protrusions 467a, 469a and protrusions 467b, 469b. The legs 493 do not extend the complete height of the third sections 448c, 450c, 462c, 464c. On one side of the lens 481, leg 491 seats between the protrusions 463a, 465a and the base wall 386 of the upper housing 421; on the other side of the lens 481, the other leg 491 seats between the protrusions 467a, 469a and the base wall 386 of the upper housing 421 provided on that side of the heat sink 424. As the legs 491 are pushed into the heat sink 424, the locking nubs 471, 495 engage with each. In the final pushed-in configuration, surfaces 501 and 477 abut each other. This prevents removal of the lens 481 once assembled with the electrical path assembly 426.

The base 483 can be formed of plated plastic and can include a cylindrical male portion 502 (which is the part that is plated) which has a base wall 503 extending outwardly from the perimeter of the male portion 502. The cylindrical male portion 502 may have threads formed thereon during plating for screwing into a conventional lamp (if the base is a Edison-type base). First and second pairs of spaced apart legs 504, 505 extend upwardly from the top side of the base wall 503. Each leg 504, 505 is generally rectangular, except each leg 504 has a locking nub 506 thereon which extends outwardly therefrom in a direction which is away from the leg 505. The locking nub 506 includes an upper surface 507 which is perpendicular to the surfaces of the leg 504, an inner surface 508 which angles downwardly and outwardly from the leg 504, and a bottom surface 509 which is perpendicular to the surfaces of the leg 504.

The base 483 is snapped onto the electrical path assembly 426 using the locking nubs 471, 506. The legs 504, 505 of the base 483 are inserted into the respective slots 454, 468 of the heat sink 424. On one side of the base 483, leg 505 seats between protrusions 463a, 465a and protrusions 463b, 465b; on the other side of the base 483, the other leg 505 seats between protrusions 467a, 469a and protrusions 467b, 469b. The legs 505 do not extend the complete height of the third sections 448c, 450c, 462c, 464c. On one side of the base 483, leg 504 seats between the protrusions 463a, 465a and the base wall 386 of the lower housing 421; on the other side of the base 483, the other leg 491 seats between the protrusions 467a, 469a and the base wall 386 of the lower housing 421 provided on that side of the heat sink 424. As the legs 504 are pushed into the heat sink 424, the locking nubs 471, 506 engage with each. In the final pushed-in configuration, surfaces 591 and 477 abut each other. This prevents removal of the base 483 once assembled with the electrical path assembly 426.

The ends of the pins 476, 478 are appropriately sized and routed through the Edison-type base 483, and have solder provided thereon to provide resistor leads 510, 512 which are on the exterior of the base 483.

It is to be understood that other shapes may be provided for the locking nubs 471, 495, 506 than those provided therein. Also, other means for joining the lens 481 with the electrical path assembly 426 and the base 483 with the electrical path assembly 426 are within the scope of the present invention. Also, while a base with an Edison-type shape is shown and described, other base shapes can be provided so that the base mates with the desired socket.

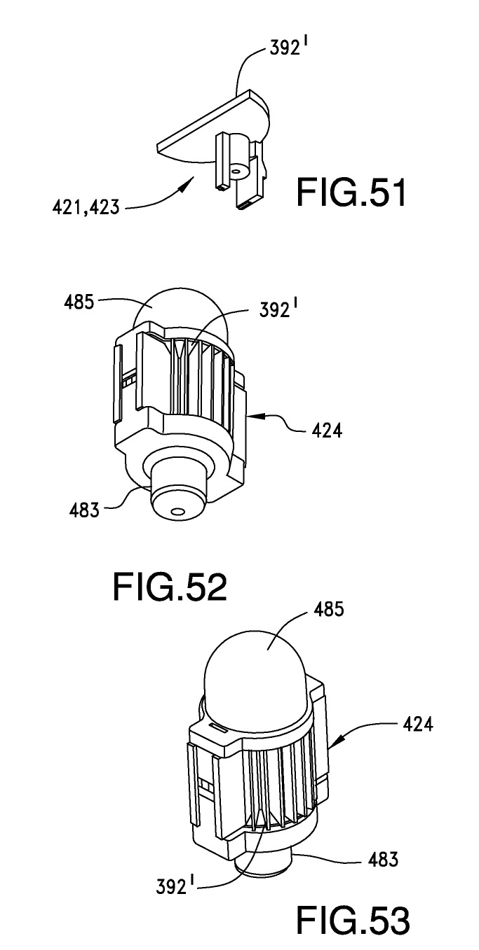

As shown in FIGS. 51-53, the housings 421, 423 are modified to enclose the ends of the pins 376, 378. The housing 421, 423 are identically formed to that described with respect to the fourth embodiment, except that the cap is enlarged (the cap is shown with reference numeral 392′), such that the cap 392′ is formed as a semi-circle. When the sleeves 472, 474 and pins 476, 478 are assembled with the heat sink 424 as discussed herein, the modified cap 392′ abuts against and covers the bottom surface and the top surface of the heat sink 424. Therefore, the ends of the pins 376, 378 are not exposed to the outside.

It should be noted that as the lens 485 is likely to have some reflective property, it may be beneficial to provide a highly reflective shield (with either a specular or a diffuse configuration) over the heat sink 24 or incorporate a highly reflective shield into the cap 392′ so that substantially all the light is directed out of the lens 485. The reflective shield may be incorporated in the lens 485 or may a separate component. The lens 485 can be configured to shape the emitted light in a desired pattern.

In the embodiments incorporating a resistor 353, 453, it is to be noted that a single resistor 353, 453 may be used and therefore one side of the heat sink 324, 424 may configured differently (for example, as pictured in one of the other embodiments). While the use of a resistor 353, 453 tends to decrease the efficiency of the system, depending on the design of the LED device 20 and the design of the power source or circuit member, an increase in the impedance may be required. Therefore, these depicted embodiments allow for an efficient method of including a resistor 353, 453 in the packaging. Furthermore, an additional benefit is that the resistor 353, 453 can utilize the heat sink 324, 424 to improve heat transfer away from the resistor 353, 453 without being packaged close to the LED device 20 (thus helping to improve heat transfer away from the LED device 20).

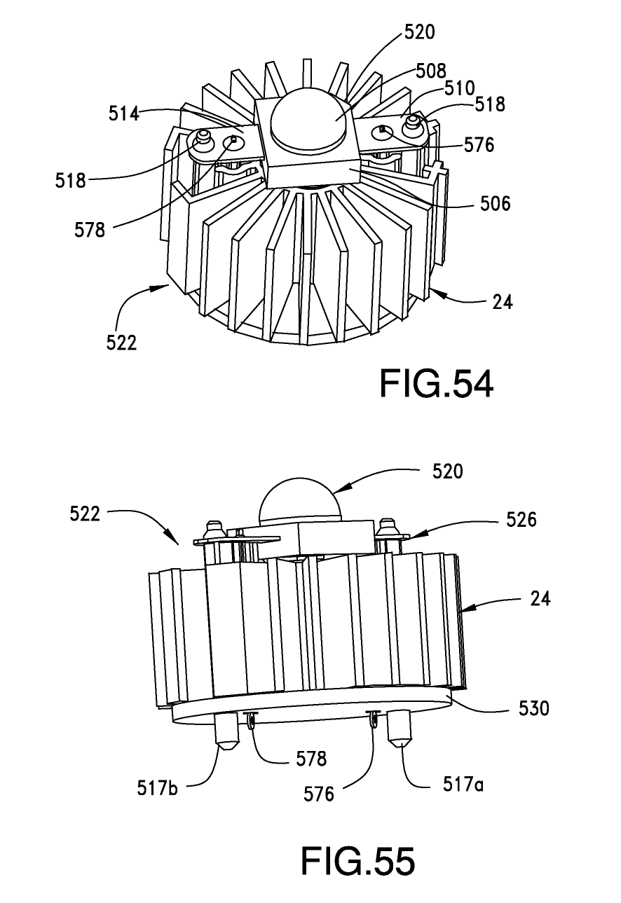

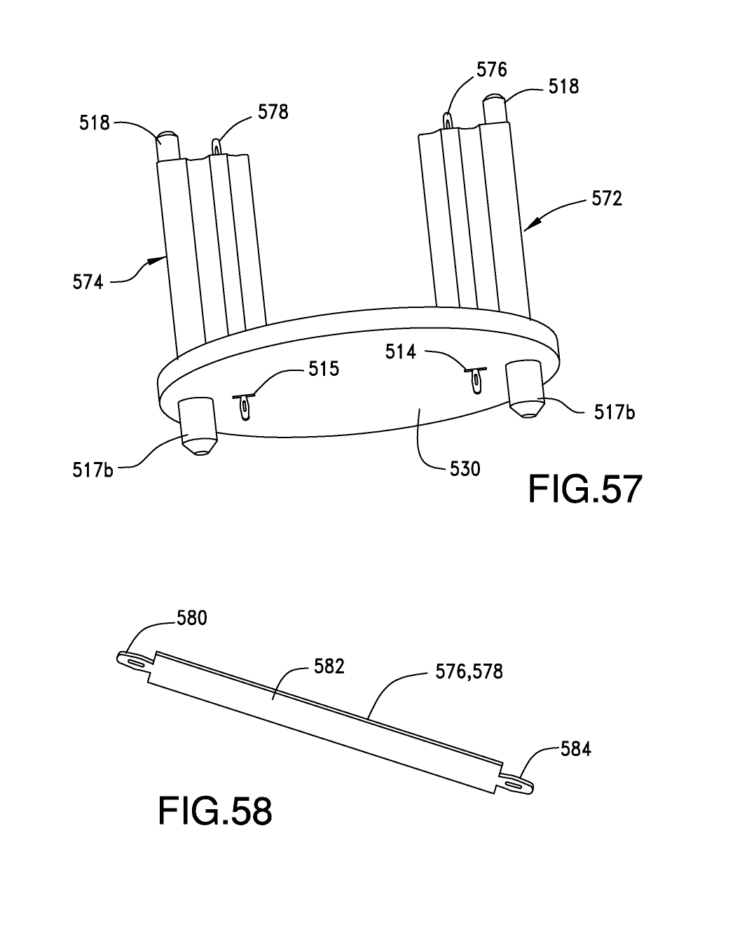

Attention is invited to the fifth embodiment of an assembly 522 shown in FIGS. 54-60. The assembly includes a LED device 520, the heat sink 24, an electrical path assembly 526. While a top insulator 30 is not shown, it is to be understood that one can be provided, depending upon the type of LED device 20 used. The heat sink 24 is identical to that shown in the first embodiment. Therefore, the specifics of the heat sink 24 is not repeated.

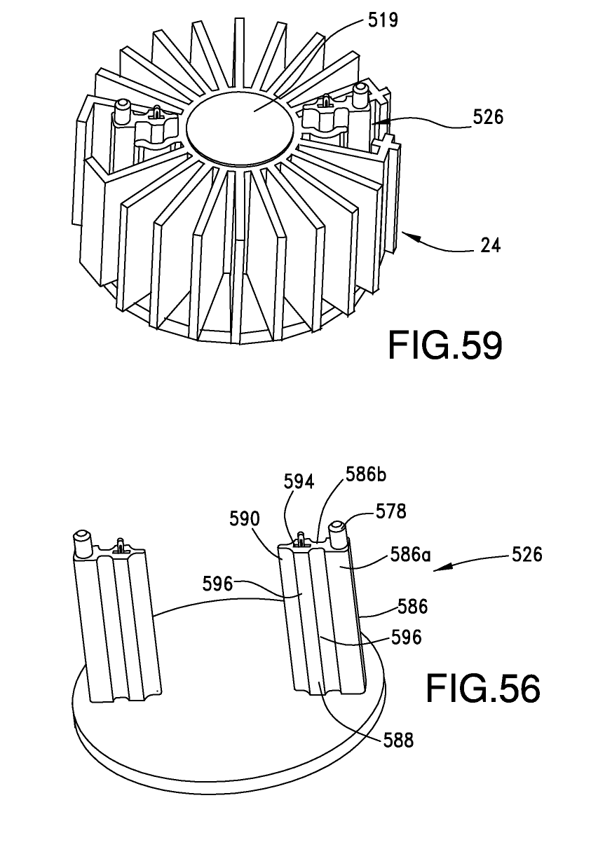

The electrical path assembly 526 is used to connect the LED device 20 to the power source or circuit member (not shown) and is best shown in FIG. 56. The electrical path assembly 526 includes first and second sleeves 572, 574, first and second pins 576, 578 and a bottom insulator 530. The sleeves 572, 574 are mounted within the channels 41, 43 of the heat sink 24.

The first and second sleeves 572, 574 and bottom insulator 530 are dielectric and are integrally formed and may be molded. The bottom insulator 530 is a plate having a pair of slits 514, 515 provided therethrough and a pair of mounting feet 517a, 517b extending downwardly therefrom. As shown, the bottom insulator 530 is circular, however, it is not limited to this shape. The sleeves 572, 574 extend upwardly from the bottom insulator 530. Sleeve 572 is described with the understanding that sleeve 574 is identically formed.

The sleeve 572 has an elongated base wall 586, an elongated tubular wall 588 extending from the base wall 586, an elongated finger wall 590 extending outwardly from the tubular wall 588, and a peg 518.

The base wall 586 has a first enlarged section 586a and a second reduced section 586b. The tubular wall 588 extends from the second reduced section 586b. The width of the enlarged section 586a is greater than the width of the reduced section 586b. The reduced section 586b has a dimension which is slightly less than the width of the slot 54, 68 between the ends of the electrical path retaining fins 40, 40′; 42, 42′. The peg 518 extends upwardly from the first enlarged section 586a.

The tubular wall 588 has a central passageway 594 therethrough. The central passageway 594 aligns with the respective slit 514, 515 in the bottom insulator 530. Elongated ribs 596 are provided at spaced apart locations on the exterior of the tubular wall 588. As shown, the tubular wall 588 is a flattened cylinder, but it is not limited to this shape, provided the gaps 56, 70 in the heat sink 24 mirror the shape of the wall 588. The tubular wall 588 extends along the entire height of the base wall 86.

The finger wall 590 extends from the diametrically opposed side of the tubular wall 588 to that from which the base wall 586 extends. The finger wall 590 has a width which is substantially less than the width of the tubular wall 588. The finger walls 590 of the sleeves 572, 574 face each other.

Each pin 576, 578 is electrically conductive, and as best shown in FIG. 58, includes a head 580 and an elongated flat shank 582 extending therefrom to a tip 584. Other tips than that shown in FIG. 58 may be provided, such as the solder tip 84 of the first embodiment of the forms as shown in FIGS. 18A-18D. The pins 576, 578 are mounted in the central passageway 594 of the respective tubular wall 588 and extend through the bottom insulator 580. The head 580 of the pins 576, 578 extend upwardly from the tubular wall 588 and the tip 584 of the pins 576, 578 extend downwardly from the bottom insulator 530.

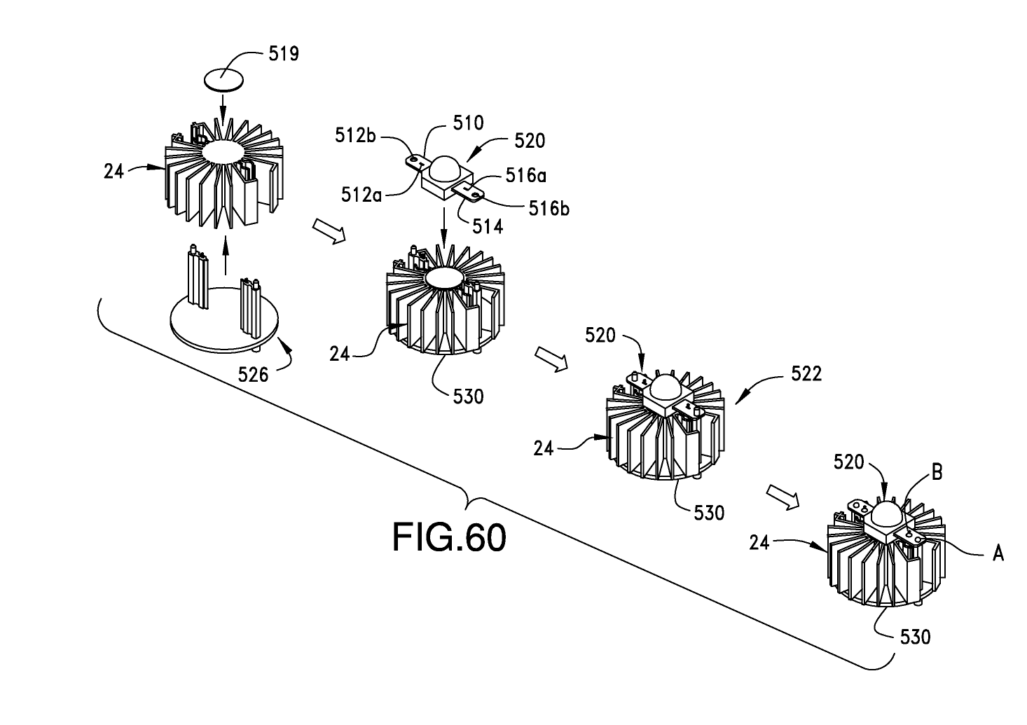

As shown in FIG. 60, the LED device 520 is formed from a substrate 506 on which at least one LED is provided. A lens cover 508 is provided over the at least one LED. A first lead 510 has an end electrically connected, for example by wire bonding, to the silicant in the substrate 506, and the other end of the first lead 510 has first and second apertures 512a, 512b. The first pin 576 passes through the first aperture 512a to electrically connected the first lead 510 to the first pin 576. The peg 518 on sleeve 572 passes through the second aperture 512b. A second lead 514, which is electrically isolated from the first lead 510, has an end electrically connected, for example by wire bonding, to the silicant in the substrate 506, and the other end of the second lead 514 has first and second apertures 516a, 516b. The second pin 578 passes through the first aperture 116a to electrically connected the second lead 514 to the second pin 578. The peg 518 on sleeve 574 passes through the second aperture 516b. The pins 576, 578 form an anode and a cathode for the LED device 520. A slug, which is formed of a solid piece of metal, is attached to the bottom surface of the substrate 506. The slug provides the interface that transfers heat to the atmosphere.

The sleeves 572, 574 and bottom insulator 530 are assembled with the heat sink 24 prior to attachment of the LED device 520. The sleeves 572, 574 are inserted between the respective electrical path retaining fins 40, 40′; 42, 42′. For sleeve 572, the finger wall 590 is inserted into the pocket 52, the tubular wall 588 is inserted into the gap 56 and the reduced section 586b of the base wall 586 is inserted into the slot 54; the enlarged section 586a of the base wall 586 is outside of the ends of the fins 40, 40′. For sleeve 574, the finger wall 590 is inserted into the pocket 66, the tubular wall 588 is inserted into the channel 70 and the reduced section 586b of the base wall 586 is inserted into the slot 68; the enlarged section 586a of the base wall 586 is outside of the ends of the fins 42, 42′. During assembly, the ribs 596 on the sleeves 572, 574 may be crushed against the interior surfaces of the arcuate second sections 48b, 50b; 62b, 64b to form a friction fit between the sleeves 572, 574 and the fins 40, 40′; 42, 42′. If the ribs 596 are crushed, this aids in providing mechanical stability between the LED device 520, the sleeves 572, 574 and the heat sink 24 in the final assembly, which protects the electrical connection and the thermal connection. The attachment formed between the sleeves 572, 574 and the electrical path retaining fins 40, 40′; 42, 42′ by the friction fit may be augmented by thermally conductive adhesive provided between the sleeves 572, 574 and the electrical path retaining fins 40, 40′; 42, 42′.

When the sleeves 572, 574 are fully inserted, the bottom insulator 530 abuts against the bottom end of the heat sink 524. As a result, the tip 584 of each pin 576, 578 extends downwardly from the heat sink 24. The ends of the pins 576, 578 can be friction fit, or otherwise secured, to the power source or circuit member. The mounting feet 517a, 517b are fit into appropriate holes on the power source or circuit member. It is to be noted that the mounting feet 517a, 517b may be configured so that a keyed configuration is presented (for example, one mounting foot could be a different shape or size than the other mounting foot). Furthermore, a single, non-circular shaped mounting foot may be sufficient to mount in the power source or circuit board. However, depending on the mass of the heat sink 24, it may be beneficial to spread the force exerted by the heat sink 24 over a wide location by using the two mounting feet (or some greater number of mounting feet as desired).

The assembly of the electrical path assembly 526 with the LED device 520 is shown in FIG. 60. First, thermal management tape 519, which is adhesive on both sides and may, if desired, be cross-linked later in the process by heating the final assembly, is applied to the upper surface of the base 32. To assemble the LED device 520 with the electrical path assembly 526, the first and second leads 510, 514 of the LED device 520 are seated on top of the walls 586, 588, 590 such that the substrate 506 of the LED device 520 is between the finger walls 590 and abuts that thermal management tape 519, the apertures 512a, 516a engage over the heads 580 of the pins 576, 578, and the apertures 512b, 516b engage over the pegs 518 on the sleeves 572, 574. The LED device 20 first engages the pegs 518 the sleeves 572 such that the pegs 518 guide the LED device 20 onto the heads 580 of the pins 576, 578.

Therefore, an anode of the LED device 520 is formed by the first lead 510 and the first pin 576, and a cathode of the LED device 520 is formed by the second lead 514 and the second pin 578. The anode and the cathode are electrically isolated from each other by the top insulator 28 (if provided), the sleeves 572, 574 and the bottom insulator 530. This provides for an electrical path between the power source or circuit member and the LED device 520. As a result, a heat sink function and an electrical path retaining function are provided. During operation of the LED device 520, the LED device 520 generates heat which is transferred to the base 532 and to the fins 34, 36, 36′, 38, 38′, 40, 40′, 42, 42′, and this heat must be removed. As air is circulated around the base 532 by known means, the heat is removed.

If desired, after assembly of the electrical path assembly 526, the heat sink 24 and the LED device 520, the pegs 518 can be heat-staked (mushroomed over) as shown at A in FIG. 60 to provide a redundant lock. Also, if desired, the heads 80 of the pins 576, 578 can be soldered to the leads 510, 514 of the LED device 520 as shown at A in FIG. 60.

As illustrated in the drawings, the pins are mounted to the LED device and are configured to be coupled to an electrical circuit. It should be noted that a number of methods exist for coupling something like a pin to an electrical circuit, therefore the depicted embodiments for coupling to a circuit are, unless otherwise noted, not intended to be limiting. The electrical circuit may include a single LED device or may include a plurality of LED devices positioned in series or in parallel.

It should be noted that while the depicted heat sinks are an extruded design, the heat sink could be incorporated in a housing (such as a fixture housing) and apertures in the housing could be configured to match the sleeves. As can be appreciated, the depicted designs are well suited to increase surface area so as to improve heat transfer away from the LED device, but as heat generation per lumen decreases, a thinner, more integrated heat sink may be utilized.

The heat sink is depicted in configurations that are well suited to an extruded manufacturing process. The advantage of using an extruded process is the ability to create radial fins, as well as the ability to readily create gaps that extend through the heat sink. Other manufacturing processes may also be used to create the heat sink. For example, die cast and folded fin technologies are known alternative methods of creating heat sinks If the heat sink requirements are reduced or the area is sufficient, the heat sink may also be a stamping.

It should be noted that while certain features have been illustrated with particular embodiments, it is envisioned that these features may also be used with other embodiments. Therefore, unless otherwise noted, depicted features may be combined in combinations that are not expressly illustrated.

While preferred embodiments of the present invention are shown and described, it is envisioned that those skilled in the art may devise various modifications of the present invention without departing from the spirit and scope of the appended claims.

The invention claimed is:

1. An assembly comprising:
a conductive heat sink with a first surface and a second surface, the heat sink including a first channel extending from the first surface to the second surface and a second channel extending from the first surface to the second surface;
a solid state lighting (SSL) engine mounted on the first surface; and
a first conductive pin extending through the first channel and electrically coupled to the SSL engine;
a first dielectric sleeve which at least partially surrounds the first pin for electrically isolating the first pin from the conductive heat sink;
a second pin extending through the second channel and electrically coupled to the heat generating device; and
a second dielectric sleeve which at least partially surrounds the second pin for electrically isolating the second pin from the conductive heat sink.

2. An assembly as defined in claim 1, wherein the first sleeve is at least partially mounted within the first channel.

3. An assembly as defined in claim 2, wherein the first sleeve mirrors the shape of the first channel.

4. An assembly as defined in claim 2, wherein the second sleeve is at least partially mounted within the second channel and the first and second sleeve are coupled together by a dielectric plate.

5. An assembly as defined in claim 1, wherein one of the first and second sleeve is formed of a first housing and a second housing, the first housing mounted on the first surface of the heat sink and the second housing mounted on the second surface of the heat sink, such that the housings are not positioned within the channels.

6. An assembly as defined in claim 5, further including a first push nut engaged with the first pin and the first housing to cause the first housing to maintain engagement with the first pin, and a second push nut engaged with the second pin and the second housing to cause the second housing to maintain engagement with the second pin.

7. An assembly as defined in claim 1, wherein one of the first and second sleeve is formed of a first housing and a second housing, the first and second housings being at least partially mounted within the first channel and mated together.

8. An assembly as defined in claim 7, wherein the first and second housings are selected from the group of being hermaphroditic and being welded together.

9. An assembly as defined in claim 1, wherein the heat sink includes a base and a plurality of spaced apart fins extending from the base and wherein the first and second channel are formed by predetermined ones of the fins.

10. An assembly as defined in claim 9, wherein predetermined ones of the fins denotes to a user, in operation, whether the channels provides for an anode or a cathode of the SSL engine.

11. An assembly as defined in claim 9, wherein the first sleeve and the second sleeve include ribs thereon which engage with the predetermined ones of the fins.

12. An assembly as defined in claim 1, wherein the SSL engine includes a first lead which is electrically coupled to the first pin, and a second lead which is electrically coupled to the second pin.

13. An assembly as defined in claim 12, wherein the first pin includes a knurl thereon which forms a serrated pattern in the first lead and the first sleeve, and the second pin includes a knurl thereon which forms a serrated pattern in the second lead and the second sleeve.

14. An assembly as defined in claim 1, wherein the SSL engine is a light emitting diode (LED) and the LED includes a slug thereon which is positioned proximate to the heat sink when the LED is mounted on the heat sink.

15. An assembly as defined in claim 1, further including an electrical insulator between the SSL engine and the first surface of the heat sink.

16. An assembly as defined in claim 1, wherein the first pin is swaged after assembly with the first sleeve, and the second pin is swaged after assembly with the second sleeve.

17. An assembly as defined in claim 1, further including a resistor mounted on the first pin, the resistor being positioned within the first channel.

18. An assembly as defined in claim 17, further including a tube surrounding the resistor, the tube engaging the first sleeve.

19. An assembly as defined in claim 1, further including a lens formed of clear or translucent material mounted on the heat sink and covering the heat generating device.

20. An assembly as defined in claim 19, wherein the lens is mated with the first and second sleeves.

21. An assembly as defined in claim 20, wherein the lens is mated with the first and second sleeve by a snap-fit connection.

22. An assembly as defined in claim 21, further including a base mounted on the heat sink for engaging an electrical socket and in electrical contact with the first and second pins.

23. An assembly as defined in claim 22, wherein the base is an Edison-type base and the Edison-type base is mated with the first and second sleeve.

24. An assembly as defined in claim 23, wherein the Edison-type base is mated with the first and second sleeve by a snap-fit connection.
